(19) United States
(12) Patent Application Publication
(10) Pub. No.: US 2026/0177808 A1
(43) Pub. Date: Jun. 25, 2026

(54) CIRCUIT COMPRISING A STEP-UP CONVERTER FOR CONTROLLING AN ACTUATOR FOR DRIVING AN OSCILLATING MOVEMENT IN AN MEMS

(71) Applicant: OQMENTED GMBH, Itzehoe (DE)

(72) Inventors: Wjatscheslaw GALJAN, Nützen (DE); Leon POHL, Schwentinental (DE); Marco MEOLA, Kiel (DE)

(21) Appl. No.: 19/127,670

(22) PCT Filed: Nov. 6, 2023
(86) PCT No.: PCT/EP2023/080863

§ 371 Date: May 6, 2025

(30) Foreign Application Priority Data
Nov. 7, 2022 (DE) 102022129371.8

(51) Int. Cl. G02B 26/08; B81B 7/00

(52) U.S. Cl. CPC G02B 26/0833; B81B 7/008; B81B 2201/042; B81B 2207/03

(57) ABSTRACT

Described are various circuits for controlling an actuator for driving an oscillating movement of at least one movable component of a microelectromechanical system (MEMS), as well as a MEMS equipped with such a circuit. The circuits have at least one MEMS capacitor which is designed as an actuator component in such a way that said MEMS capacitor forms a component of an electromechanical converter of the actuator, the converter being configured to convert electrical energy stored in the MEMS capacitor into at least one mechanical quantity for driving a movement of the actuator. The circuits contain a step-up converter circuit for generating a charging voltage for the direct, capacitor-unbuffered charging of the MEMS capacitor, and/or a pausable oscillation circuit with the MEMS capacitor as an oscillation circuit capacitor.

The present invention relates to a circuit for controlling an actuator, in particular a MEMS actuator, for driving an oscillating movement in a microelectromechanical system (MEMS), as well as a MEMS equipped therewith. The circuit comprises at least one step-up converter, in particular a boost converter, for providing an electrical supply for driving the oscillating movement. The MEMS can in particular be a microscanner system with a deflection element (mirror) arranged to oscillate, wherein the actuator is configured to drive an oscillating movement (oscillation) of the deflection element.

Many MEMS, i.e., systems with multiple components, the dimensions of which are typically in the range of 1 μm to 100 μm, wherein the MEMS themselves typically have dimensions in the range of about 10 μm to a few millimeters, have moving mechanical parts that can be driven using electrical energy, such that a microscopically small machine is provided as an electromechanical system.

Oscillating mass elements of MEMS, in particular deflection elements of microscanners, can be made to oscillate in various ways. However, this always requires a driving force that is able to deflect the deflection element (e.g., mirror plate) from its resting position. Typically, one or more actuators are used as such force-providing drives for MEMS (in particular small microphones, loudspeakers or gyroscopes, microscanners or microscanner systems having multiple microscanners), which are operated according to an electrostatic, electromagnetic, piezoelectric, thermal, or other actuator principle or according to a mixture of two or more such actuator principles.

The term “MEMS actuator,” as used herein, is to be understood in particular as an actuator that can convert electrical and/or magnetic energy into mechanical energy, and/or vice versa, and that uses a MEMS for this purpose or is itself a component thereof, in particular as the MEMS itself or as a component thereof. Such a MEMS actuator can in particular be configured to operate on the basis of a direct or inverse piezoelectric effect. Where reference is made herein to an “actuator”, this, in particular, can always be a MEMS actuator.

Microscanners, which are also referred to in technical terms in particular as “MEMS scanners,” “MEMS mirrors,” or “micromirrors,” or in English in particular as “microscanners” or “microscanning mirrors,” are micro-electro-mechanical systems (MEMS) or more specifically micro-opto-electromechanical systems (MOEMS) from the class of micromirror actuators for dynamic modulation of electromagnetic radiation, in particular of visible light. Depending on the design, the modulating movement of an individual mirror can be translational or rotational about at least one axis. In the first case, a phase-shifting effect is achieved, and in the second case deflection of the incident electromagnetic radiation is achieved. Furthermore, microscanners are considered in which the modulating movement of an individual mirror is also rotational, at least in addition. In microscanners, modulation is typically generated via a single mirror for each MEMS-element (microscanner), in contrast to mirror arrays, in which the modulation of incident light occurs via the interaction of multiple small mirrors on a single MEMS-element.

Microscanners may thus be used in particular to deflect electromagnetic radiation in order to modulate an electromagnetic beam incident thereon with respect to its deflection direction by means of a deflection element (“mirror”). This can be used in particular to achieve a Lissajous projection of the beam into an observation field or projection field. For example, imaging sensory tasks can thus be achieved or display functionalities can be implemented. In addition, such microscanners can also be used to irradiate materials in an advantageous manner and in particular to process them. Other possible applications are in the area of lighting or illuminating certain open or closed spaces or areas of spaces using electromagnetic radiation, for example in the context of headlight applications.

In many cases, microscanners have a mirror plate (“mirror”) as a deflection element that is suspended laterally on elastically stretchable springs. A distinction is made between single-axis mirrors, which should preferably be suspended so as to be rotatable only about a single axis, and two-axis and multi-axis mirrors, in which rotations, in particular rotational oscillating movements, are possible about a corresponding number of different axes, in particular simultaneously.

A microscanner system for deflecting an electromagnetic beam can thus in particular have a two-axis microscanner, i.e., a microscanner with two different, non-parallel, in particular mutually orthogonal, oscillation axes or a combination of multiple individual, in particular two, single-axis microscanners which are arranged such that the incident beam can be deflected in succession by the various individual microscanners of the microscanner system, in order to generate a bi-dimensional deflection pattern, in particular a Lissajous figure. In a microscanner system with a combination of two or three single-axis microscanners, their non-parallel oscillation axes can be orthogonal to each other, particularly in pairs.

Especially in so-called Lissajous microscanners or Lissajous microscanner systems, two non-parallel, in particular mutually orthogonal oscillation axes are operated simultaneously, in particular in resonance, in order to generate a trajectory of the deflected radiation in the form of a Lissajous figure. In this way, large amplitudes can be achieved in both axes.

Such a deflection device for a projection system for projecting Lissajous figures onto an observation field is known from EP 2 514 211 B1, which device is designed to deflect a light beam about at least a first and a second deflection axis to generate Lissajous figures.

Electrostatic, electromagnetic, piezoelectric, thermal, and other actuator principles are typically used as drives for MEMS, such as small microphones, loudspeakers, or gyroscopes, and especially for microscanners or microscanner systems. Especially in piezoelectric actuators (“piezo actuator”), a piezoelectric material is deformed in an electric field generated by an (electrical) capacitor using the inverse piezoelectric effect depending on the strength of the field. If the field is temporally variable, in particular due to a variable voltage applied to the capacitor, the result is a variable deformation of the piezo material that can be controlled by the field variation and can be used as a small motor to drive a mechanical movement, which especially in microscanners is an oscillating movement of the mirror.

However, particularly in the case of resonantly operated, oscillatory MEMS components, such as the deflection element in a microscanner, the actuator(s) are often not strong enough overall to statically deflect the oscillatory MEMS component to a desired target amplitude during operation within a single activation of the actuator(s). In order to nevertheless achieve the target deflection, the at least one actuator, in the case of a piezo actuator its piezoelectric material, must be subjected to a periodic alternating voltage, the frequency of which corresponds, at least to a good approximation, ideally exactly to the mechanical resonance frequency of the oscillating MEMS component. This results in small but always timely driving forces which, after a certain time, are able to significantly oscillate the mechanical oscillator formed by the oscillating MEMS component and its suspension or bearing, and thus gradually “charge” it with mechanical energy until the target amplitude is reached (and can possibly be maintained over a longer period of time).

From an electrical point of view, this drive process in a capacitive actuator, especially a piezo actuator, corresponds to a constant recharging of its capacitor. Especially in the case of a microscanner with a piezoelectric drive, the amplitude of the alternating voltage across the capacitor of the piezo actuator significantly influences the resulting or, in the steady state, the maximum achievable scanning angle (target amplitude) of the microscanner.

In particular when a MEMS is to be used in a device that only has a very limited amount of electrical energy or electrical power available to supply energy during operation, as is usually the case with a battery-operated, particularly portable device (such as a mobile, particularly portable device, e.g., a smartphone, or a so-called “wearable,” or AR/VR glasses or a MEMS integrated into clothing), energy-efficient drives for the MEMS are advantageous or even necessary to enable the longest possible, in particular an application-specific, sufficiently long autonomous service life of the devices.

To reduce the power consumption of the MEMS, it is therefore desirable to make the charging processes on the capacitor of the actuator as efficient as possible. In this way, the resulting total power consumption for driving the MEMS can be minimized and, in particular, the service life of the battery(ies) can be increased.

In addition, the voltage level available to the device, especially a battery voltage, is often below a voltage level required by the actuator, so that a voltage conversion is required to achieve it.

It is an object of the present invention to provide an improved circuit for controlling an actuator for energy-efficient and/or space-saving driving of an oscillating movement in a MEMS and a MEMS, in particular a microscanner system, which is equipped with such a circuit.

This object is achieved according to the teaching of the independent claims. Various embodiments and developments of the invention are the subject of the dependent claims and/or the following description, which for the sake of clarity is structured into sections each introduced by a heading, but which is not to be understood as a limitation of the content of the text sections falling under them or the figures described therein.

### Terminology

The term “MEMS capacitor,” as used herein, is to be understood as an electrical capacitor, in particular a single electrical capacitor which is at least partially designed as a component of a MEMS actuator and is configured to at least temporarily store electrical energy used for the operation of the actuator for its (proportional) conversion into mechanical energy. In particular, such a MEMS capacitor can comprise a capacitor, in particular a plate capacitor, of a piezo actuator with a piezoelectric material as a dielectric. a MEMS capacitor can be designed in particular as an integrated component of a MEMS, in particular such that the electrodes and the dielectric of the MEMS capacitor each form a layer of a layer sequence produced in or on a semiconductor substrate.

The term “control(ler),” as used herein, is to be understood in particular as a process or a device (control device) configured to carry out such a process, which device is adapted to control one or more components of a circuit, including in particular one or more of its switching devices, in the sense of an open-loop or closed-loop control via corresponding signals. In particular, it may be or comprise a computer-programmed microcontroller or a hard-wired control circuit. Such a control device can in particular itself be part of the circuit.

The term “step-up converter” (or “step-up converter”), as used herein, refers to a form of DC-DC converter that is configured to convert an input voltage into an output voltage such that the magnitude of the output voltage is greater than the magnitude of the input voltage. The term is not limited to a specific topology or type of such a DC-DC converter.

The term “switching device,” as used herein, means a circuit or component thereof which is or comprises at least one circuit or component acting as a switch. In particular, the switching device may comprise one or more switches. In particular, the device can be implemented using one or more semiconductor components such as transistors or diodes. For example, a single transistor or a CMOS gate can act as a switch, if appropriately controlled. A diode can also act as a switch, especially in the forward direction, if a voltage applied across it is either above its threshold voltage (in the forward direction) or below its breakdown voltage (in the reverse direction).

The term “capacitor-unbuffered,” as used herein, is to be understood with respect to a current path as meaning that this current path is not buffered via a capacitor in the sense of a voltage buffer, in particular not in the sense of a buffer capacitor. Thus (apart from any parasitic capacitors) there is no capacitive component (in particular, capacitor) for buffering (i.e., supporting) the input voltage or the input current of the component or circuit part controlled via the current path, in particular the actuator. In particular, any remaining parasitic capacitor of the current path may be in the range of less than or equal to 40 pF, in particular less than or equal to 10 pF.

The term “current source,” as used herein, means an active two-terminal device that supplies an electrical current at its connection points. As an essential property, the strength of this current depends only slightly (“real” current source) or not at all (“ideal” current source) on the electrical voltage at its connection points.

The term “a resonant frequency related to a permanently closed state of the oscillation circuit,” as used herein, is to be understood as a resonant frequency of the oscillation circuit which it has in the steady state when it is permanently closed, i.e., at least beyond the transient process, i.e., in particular is not interrupted by the first switching device. In an ideal oscillation circuit (i.e., when ohmic resistances R are negligibly small), the resonance frequency is f₀:

$${f}_{0} = \frac{1}{2 π \sqrt{L C}} \qquad ( 1 )$$

wherein C is the capacitor and L is the inductor of the oscillation circuit. In the real oscillation circuit, the resonance frequency is lower due to the ohmic losses in the resistors R, depending on the strength of this damping.

The term “step-up converter,” as used herein, means a voltage converter of any type and/or topology that generates an output voltage from an input voltage by voltage conversion or can generate one in at least one operating mode, such that the magnitude of the output voltage is greater than the magnitude of the input voltage. For this purpose, a step-up converter may in particular comprise one or more step-up converters and/or one or more charge pumps.

As possibly used herein, the terms “comprises,” “contains,” “comprises,” “has,” “having,” “with,” or any other variant thereof are intended to cover non-exclusive inclusion. For example, a method or a device that comprises or comprises a list of elements is not necessarily restricted to these elements, but may comprise other elements that are not expressly listed or that are inherent to such a method or such a device.

Furthermore, unless expressly stated to the contrary, “or” refers to an inclusive or and not to an exclusive “or.” For example, a condition A or B is met by one of the following conditions: A is true (or present) and B is false (or absent), A is false (or absent) and B is true (or present), and both A and B are true (or present).

The terms “a” or “an” as used herein, are defined in the meaning of “one or more.” The terms “another” and “a further” and any other variant thereof are to be understood to mean “at least one other.”

The term “configured” or “designed” to perform a specific function (and respective modifications thereof), possibly used herein, is to be understood to mean that the corresponding device or a component thereof is already provided in a design or setting in which it can execute the function or that it is at least adjustable-namely configurable-so that it can execute the function after corresponding adjustment. The configuration can take place, for example, via a corresponding setting of parameters of a process course or of switches or the like for activating or deactivating functionalities or settings. In particular, the device can have multiple predetermined configurations or operating modes, so that the configuration can be carried out by selecting one of these configurations or operating modes.

The terms “first,” “second,” “third,” and similar terms in the specification and claims are used to distinguish between similar or otherwise like-named elements and are not necessarily descriptive of a sequential, spatial, or chronological order. It should be understood that the terms so used are interchangeable under appropriate circumstances, and that the embodiments described herein may operate in different orders than those described or illustrated herein.

Circuit with Step-Up Converter (“First Circuit”)

A first aspect of the solution presented here relates to a first circuit for controlling an actuator, in particular a MEMS actuator, for driving an oscillating movement of at least one movable component of a microelectromechanical system, MEMS. The first circuit can be used in particular to control an actuator for driving a mirror movement in a microscanner system.

It comprises a step-up converter circuit with an inductor (hereinafter referred to as “booster inductor” to distinguish it from other inductors mentioned below, in particular including one or more coils), an electrical MEMS capacitor, and a switching device which can be controlled by means of a controller. The MEMS capacitor is designed as a component of an actuator in such a way that it forms a component of an electromechanical converter of the actuator, wherein the converter is configured to convert electrical energy stored in the MEMS capacitor into at least one mechanical variable for driving a movement of the actuator (in particular at least one component thereof). The switching device is configured to assume a first circuit configuration depending on the controller and sequentially thereafter, in particular alternating several times with the first circuit configuration, a second circuit configuration. In this case, (i) in the first circuit configuration, a first current path through the booster inductor is continuously connected in order to cause an increasing current flow through the booster inductor fed by a supply voltage, and (ii) in the second circuit configuration, a capacitor-unbuffered second current path (apart from possible parasitic capacitors) is continuously connected between a first pole of the booster inductor and the MEMS capacitor in order to charge the MEMS capacitor to a first voltage using a current flow fed at least partially by the booster inductor (in particular as a current source), which is equal to or higher in magnitude than the supply voltage.

The supply voltage can in particular be generated by the circuit itself or can be supplied to it externally.

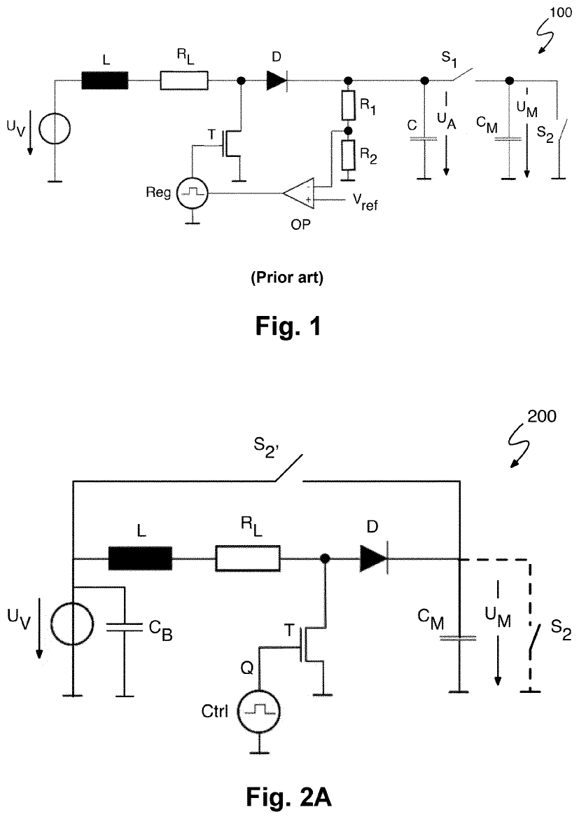

In the first circuit, the electrical energy supplied via the second current path between a first pole of the booster inductor and the MEMS capacitor is available largely undiminished in order to charge and thus supply the MEMS capacitor of the actuator and thus its function by means of a current flow fed at least partially by the booster inductor at a voltage level that is increased compared to the supply voltage. The so-called “capacitor paradox” or “two-capacitor paradox” that occurs in conventional step-up converters (see FIG. 1 and the corresponding figure description), which theoretically limits the efficiency to a maximum of 50% (see https://en.wikipedia.org/wiki/Two_capacitor_paradox), can be avoided here, since no constellation with two capacitors that can be switched in parallel via a switch is required in the voltage amplification path of the step-up converter.

In this way, the first circuit results in a significantly reduced electrical power requirement for controlling the actuator, such that the first circuit including the actuator can be used in particular in devices for which only a very limited amount of electrical energy or electrical power is available for power supply during operation.

Various preferred exemplary embodiments of the first circuit are initially described hereinafter, which in each case, unless expressly excluded or technically impossible, can be combined as desired with one another and with other aspects of the present solution, which will be described in the following.

In some embodiments, the controller is unregulated. Consequently, there is no closed-loop control within the framework of the control, but only pure control (in the sense of “open loop”) without a control circuit. Accordingly, the first circuit can be simplified compared to a regulated control, since in particular no controller and no feedback (control loop) are required and the circuit components required for this can thus be omitted. This makes it possible to implement particularly space-saving solutions. This is particularly possible because during periodic operation, i.e., a periodically alternating change between the two circuit configurations of the switching device, the voltage across the MEMS capacitor can be modeled essentially, i.e., to a good approximation, as a linear function of the period duration or, more precisely, the duration of the first circuit configuration. Thus, even an open-loop control without regulation can be sufficient for a sufficiently precise adjustment of the voltage across the MEMS capacitor and thus control of the actuator with good accuracy. In addition, energy losses associated with closed-loop control are eliminated, such that the power consumption of the first circuit can be further reduced and thus its efficiency can be further increased.

In some embodiments, the switching device is further configured to repeatedly temporarily switch a third current path continuously, in particular depending on the controller, such that the MEMS capacitor can be repeatedly, at least partially, discharged via this third current path in order to generate a supply voltage of the electromechanical converter at the MEMS capacitor which is variable in magnitude over time. Continuous switching and the resulting discharging can occur periodically. By discharging, a charge state of the MEMS capacitor can be created that leads to a lower voltage across the MEMS capacitor and thus to a correspondingly lower input voltage at the actuator than in the charged charge state (which is achieved during the second configuration of the switching device). In this way, the actuator can be switched between at least two states (charged/discharged), which via the electromechanical conversion correspond to two different mechanical states of the actuator. With an alternating, in particular periodic, change between the two charge states, a corresponding, in particular periodic, mechanical movement can be brought about at the actuator, which can be used to drive a movement, in particular an oscillating movement, in a MEMS (such as a mirror movement, in particular mirror oscillation of a microscanner system).

In some embodiments, the third current path is led to a buffer capacitor for buffering the supply voltage in order to transfer charge from the MEMS capacitor to the buffer capacitor when it is discharged. In this way, the charge introduced into the MEMS capacitor during charging can be at least partially recovered and used for a subsequent charging process. In this way, the power consumption of the first circuit can be further reduced and thus its efficiency can be further increased. In this variant, the third current path is also referred to as the fourth current path to distinguish it from an alternative current path according to another variant for discharging without charge return or buffering.

In some embodiments, the switching device is further adapted, in particular depending on the controller, to repeatedly and temporarily establish a fourth current path between the MEMS capacitor and a second pole of the booster inductor that is electrically opposite to the first pole, in a period in which the second current path is not continuously connected, such that the MEMS capacitor is charged to a second voltage with a polarity opposite to the polarity of the first voltage. In this way, bipolar operation can be enabled, in which the polarity changes across the MEMS capacitor, especially in an alternating manner. Accordingly, when using an actuator, such as a piezo actuator, which operates in a polarization-dependent manner, different actuator states can be achieved depending on, and in particular in time with, the change in the polarity of the voltage across the MEMS capacitor. In particular, such a bipolar drive with positive and negative voltages can halve the power consumption again-compared to a unipolar drive—using only one positive and one negative voltage if the same voltage amplitude (Vₘₐₓ−Vₘᵢₙ) is considered.

In some of these embodiments, the circuit device comprises: (i) a first switch, S₁, for switching an electrical connection between the supply voltage and the second pole of the booster inductor; (ii) a second switch, S₂, electrically connected to the first pole of the booster inductor, for switching the first current path through or interrupting it; (iii) a third switch, S₃, electrically connected to the first pole of the booster inductor, for switching the second current path through or interrupting it; and (iv) a fourth switch, S₄, electrically connected to the second pole of the booster inductor and the MEMS capacitor, for switching the fourth current path through or interrupting it. In this way, bipolar implementation of the first circuit as mentioned above can be achieved in a very efficient, particularly component saving and thus space and energy saving way, using only four switches in the switching device.

The term “electrically connected” in this case means a direct electrical connection without intermediate circuit components (i.e., components) or an indirect connection via one or more intermediate circuit components (i.e., components), e.g., resistors, wherein the connection can in particular have the characteristic of a (small) ohmic resistance R, e.g., with R≤10Ω.

In some embodiments, the circuit further comprises a fifth switch, S₅, for switching a current path between the second pole of the inductor and ground on or off.

In particular, according to some of the embodiments, the controller can be configured to put the circuit device into different switching states step by step according to the following sequence, wherein the sequence is run through at least once, preferably multiple times, in particular periodically:
(a) S₁ and S₂ closed, S₃ and S₄ open;
(b) S₁ and S₃ closed, S₂ and S₄ open;
(c) S₂ and S₃ closed, S₁ and S₄ open;
(d) S₁ and S₂ closed, S₃ and S₄ open;
(e) S₂ and S₄ closed, S₁ and S₅ open;
(f) S₂ and S₃ closed, S₁ and S₄ open.

In some of these embodiments, the first circuit comprises a buffer capacitor, in particular a capacitor, for capacitive buffering of the supply voltage. The sequence also comprises an additional switching state (b1) which lies between the switching states (b) and (c) and is characterized in that in this state S₁ and S₄ are closed and S₂ and S₃ are open. Thus, when discharging the MEMS capacitor, charge from the MEMS capacitor can be transferred to the buffer capacitor to be available for another switching cycle, such that the corresponding amount of charge does not have to be provided by the supply voltage source. In this way, power consumption is reduced and the efficiency of the (bipolar) first circuit is further increased.

In some embodiments, the sequence comprises, in addition (to states (a) to (f) and optionally also to (b1)), a further switching state (b2) which lies between switching states (b) and (c) and is characterized in that in this state S₂ and S₄ are closed and S₁ and S₃ are open. Thus, when discharging the MEMS capacitor, charge from the MEMS capacitor can be conducted through the booster inductor in order to charge it at least partially with energy (in its magnetic field) for a further switching cycle, such that the energy charge resulting from this current does not have to be subsequently made available to the booster inductor from the supply voltage source instead. In this way, power consumption can be reduced and the efficiency of the (bipolar) first circuit can be further increased.

In some embodiments, the sequence additionally comprises a further switching state (e1) which follows the switching state (e) and precedes the switching state (f) and which is characterized in that in this state S₄ and S₅ are closed and S₁, S₂, and S₃ are open. This allows energy recovery even from negative voltages across the MEMS capacitor C_{M} (following switching state (e1)).

In some embodiments, the controller (more precisely the corresponding control device) comprises a multi-stage delay chain and a multiplexer for tapping the respective output signals of the stages of the delay chain in a time-staggered manner to generate a time-variable control signal for controlling the switching device. The delay elements of the delay chain can be designed in particular from standard cells or as specially defined (“customized”) analog components or circuit parts, wherein the required delay of the individual stages can be calculated from the quotient of the maximum required switch-on time (duration of the first circuit configuration) and the number of stages. The analog design would have the advantage that the delay time of each individual delay element can be adjusted by setting a driver current for the delay elements (current control, see “current-starved” inverter), and thus could be optimally adjusted for any MEMS capacitors (with different capacitor values and output voltages).

In particular, according to some of these embodiments, the switching device can be controlled by means of the control signal such that switching between the first switching configuration and the second switching configuration, or vice versa, can be effected by means of the control signal.

In this way, a controller for the circuit, in particular for its switching device, can be implemented in a simple and energy-efficient manner.

Circuit with a Pausable Oscillation Circuit (“Second Circuit”)

A second aspect of the solution relates to a second circuit for controlling an actuator, in particular a MEMS actuator, for driving an oscillating movement of a mass element in a MEMS. In particular, control can be regulated or unregulated.

This second circuit comprises:
(i) an electrical oscillation circuit which contains a first inductor (hereinafter referred to as “oscillation circuit inductor” to distinguish it from other inductors mentioned below, in particular having one or more coils), a first electrical MEMS capacitor, and a first switching device (hereinafter also referred to as “oscillation circuit switch”) which can be controlled, in particular by means of a control signal, for selectively interrupting or closing the oscillation circuit in dependence on a control of the first switching device and comprises a resonant frequency related to a permanently closed state of the oscillation circuit; and
(ii) a controller for controlling the first switching device.

The controller is configured to temporarily place the first switching device during a respective oscillation period of the oscillation circuit by means of a corresponding control, in particular for a specific portion of the oscillation period, into a state in which it interrupts the oscillation circuit in order to effect an actual oscillation frequency of the oscillation circuit which is lower than the resonance frequency.

With the second circuit, the effective oscillation frequency of the oscillation circuit can be variably adjusted using the first switching device. The temporary interruption of the oscillation circuit causes a corresponding pause of the electrical oscillation in the oscillation circuit (“paused oscillation circuit”), which leads to an effective oscillation frequency below the resonant frequency of the oscillation circuit (in a permanently closed state).

Thus, the lower effective oscillation frequency can be achieved without having to increase the values of the (first) MEMS capacitor C or the (first) inductor L according to relationship (1) (see section “Terminology” above). If oscillating components of a MEMS cannot or should not exceed a certain upper limit frequency with respect to their oscillation frequency, then the above-mentioned concept of the pausable oscillation circuit allows effective oscillation frequencies to be achieved, and in particular to be set variably, which are at or below the limit frequency, although values for C and L are used for this purpose, from which a resonance frequency above the limit frequency f₀ results according to relationship (1). In particular, smaller and thus space-saving inductors L and/or MEMS capacitors (especially capacitive loads) C can be used, thereby reducing or keeping the space required for the circuit to control the actuator small.

Furthermore, the energy temporarily stored periodically in the first inductor is used or co-used to recharge the MEMS capacitor and thus to operate the actuator fed by it, such that a particularly low-consumption (periodic) control of the actuator can be realized. Due to its small space requirement and its high energy efficiency, the circuit is particularly suitable for use in mobile applications, above all in portable devices with small dimensions (e.g., in so-called “wearables”).

The option of being able to variably adjust the effective oscillation frequency for given values for C and L using the control by means of the first switching device can also be advantageously used to compensate for component tolerances, in particular in the context of mass production.

Preferred exemplary embodiments of the second circuit are described hereinafter, which in each case, unless expressly excluded or technically impossible, can be combined as desired with one another and with other aspects of the present solution, which will be described in the following.

In some embodiments, the MEMS capacitor is configured as a component of the actuator such that it forms a component of an electromechanical converter of the actuator. The converter is configured to convert electrical energy stored in the MEMS capacitor into at least one mechanical variable for driving a movement of the actuator. The actuator can in particular be a MEMS actuator, e.g., a piezo actuator. The voltage drop across the MEMS capacitor during the electrical oscillation in the oscillation circuit can thus be made available to the actuator directly and without further capacitive buffering, so that high efficiency of the second circuit can be achieved.

In some embodiments, the controller is configured to place the first switching device in a respective oscillation period of the oscillation circuit into a state in which it interrupts the oscillation circuit when the voltage across the MEMS capacitor reaches a maximum in magnitude within the oscillation period. The energy in the oscillation circuit is thus, at least for the most part, stored in the MEMS capacitor in the form of electrical energy during the pause in the oscillation caused by the interruption, until oscillation is continued by closing the oscillation circuit. This storage during the pause of the oscillation circuit can be largely maintained over a long period of time, at least with a low-loss MEMS capacitor, so that a correspondingly large range of values for the variable, adjustable effective oscillation frequency of the oscillation circuit can be achieved without significant energy losses (particularly those unacceptable for the respective application).

Specifically, the control circuit can be configured in particular to place the first switching device in a respective oscillation period of the oscillation circuit into a state in which it interrupts the oscillation circuit when the voltage across the MEMS capacitor reaches a maximum in magnitude within the oscillation period after a charge reversal of the MEMS capacitor taking place during the oscillation period. This ensures that the maximum available energy is used to recharge the capacitor and the oscillation circuit optimally reduces the total power consumption. This also ensures that the current in the inductor reaches a minimum or approaches zero, thus preventing voltage peaks from occurring by means of the inductor.

In some embodiments, the oscillation circuit comprises, in addition to the MEMS capacitor, a second MEMS capacitor formed separately therefrom with the same or different capacitor value (with respect to the first MEMS capacitor). The MEMS capacitor and the second MEMS capacitor are connected in the oscillation circuit such that a first pole of the MEMS capacitor is electrically connected to a first pole of the second MEMS capacitor via at least one switch of the first switching device and the oscillation circuit inductor, and the respective second poles of the two MEMS capacitors are electrically connected to one another such that they are kept at the same (constant or time-variable) electrical potential during operation of the oscillation circuit.

In this way, voltages complementary to each other in terms of their polarity can be tapped from the two MEMS capacitors. In order to achieve a desired differential voltage between the poles of this combination of MEMS capacitors that are farthest apart in terms of potential, it is therefore sufficient to charge the two individual MEMS capacitors to a voltage of a lower magnitude, since the two voltages add up. The above-mentioned principle of the pausable oscillation circuit remains, at least essentially, untouched. Such a configuration can be used particularly advantageously to achieve a differential drive of an oscillatory MEMS, in particular a drive of an oscillating movement of a deflection element of a microscanner.

Such a drive is particularly advantageous with respect to achieving the most uniform, jerk-free oscillation possible of the deflection element (mirror) of the microscanner and/or to reduce power consumption. The second MEMS capacitor can then also be designed as a MEMS capacitor of a (particularly second) actuator and thereby form part of a converter which is configured to convert electrical energy stored in the second MEMS capacitor into at least one mechanical variable for driving a movement of this actuator.

In some embodiments, the second circuit further comprises a power supply circuit for temporarily supplying electrical energy to the oscillation circuit. Thus, despite the losses that are unavoidable in reality (e.g., due to heat generation in parasitic, especially ohmic, resistors of the real circuit), radiation of electromagnetic waves at higher frequencies, or friction in the MEMS or air friction of moving parts of the MEMS), a longer, especially even permanent operation of the MEMS can be realized in which the power supply circuit can at least partially compensate for the energy losses. In this way, the energy in the oscillation circuit can be maintained or at least its dissipation can be slowed down.

In some embodiments, the power supply circuit comprises a second switching device which is configured to temporarily connect a first feed point for electrical energy to the oscillation circuit as a function of a control, in particular by the controller, in order to supply the oscillation circuit with electrical energy supplied or capable of being supplied at the first feed point. This allows the energy supply to the oscillation circuit to be precisely adjusted by means of controlling, particularly to optimize its temporal progression, to initially oscillate it or to compensate for its energy losses during subsequent operation.

Specifically, according to some embodiments, the second circuit can be configured, in particular by appropriate controlling, to temporarily close the second switching device in a respective oscillation period of the oscillation circuit when the voltage across the MEMS capacitor reaches a maximum in magnitude within the oscillation period and has the same polarity as a voltage provided by the power supply circuit at the first feed point. The MEMS capacitor is recharged accordingly when it is currently at its maximum charge within the scope of the electrical oscillation already taking place in the oscillation circuit, so that only an additional charge has to be supplied by the power supply circuit to replenish the charge of the MEMS capacitor to a target voltage. In the aforementioned case that a second MEMS capacitor is also provided in the oscillation circuit, this can be implemented accordingly, taking into account the opposite polarity.

In some embodiments, the second circuit is configured to temporarily connect the first feed point to the oscillation circuit in the respective oscillation period by means of the second switching device at a time before which two consecutive recharging processes of the MEMS capacitor of the oscillation circuit have already taken place in the oscillation period since the first feed point was last temporarily connected to the oscillation circuit by means of the second switching device. This can be particularly advantageous with respect to efficient and compact implementation, as it is then sufficient to provide only a single high-voltage source, optionally with positive or negative polarity of the output voltage. In particular, if such a high-voltage source comprises conventional coil-based step-up converters for voltage increase, a coil can be saved on a circuit board. This can be an advantage, especially when implementing the circuit using an integrated circuit (IC, e.g., ASIC), where hardly any additional IC-external components are necessary.

In some embodiments, the second circuit is configured to temporarily electrically connect the first feed point to the oscillation circuit by means of the second switching device in the respective oscillation period and thereby charge the MEMS capacitor, while the first switching device is in a state in which it electrically disconnects the oscillation circuit inductor from the first feed point. The charging current coming from the first feed point is thus fed into the oscillation circuit, more precisely into the MEMS capacitor, while the oscillation circuit is interrupted. The charging current is thus substantially used completely, i.e., particularly apart from any parasitic losses, to recharge the MEMS capacitor while the oscillation circuit inductor remains currentless at this time. In particular, this allows a very fast and effective energy supply to the oscillation circuit to compensate for any energy losses that may occur.

In some embodiments, the second circuit is configurable to adjust the amount of electrical energy supplied to the oscillation circuit in at least one oscillation period. This can be achieved in various ways. For example, the duration of the recharging can be varied over time, the current intensity of the recharging current can be adjusted (in particular by adjusting the voltage driving it), or the frequency with which recharging takes place can be adjusted, for example so that recharging only takes place every m-th period of the electrical oscillation in the oscillation circuit, wherein m>0 is a natural number.

The second circuit can in particular be configured such that the amount of electrical energy supplied to the oscillation circuit can be set individually for each oscillation period (e.g., by means of a closed-loop control) or globally for all m-th oscillation periods, where m>0 is again a natural number.

In some embodiments, the power supply circuit comprises an inductive coupling device, in particular an inductively coupled pair of coils, for temporarily inductively feeding electrical energy into the oscillation circuit. This can be provided in addition to, or as an alternative to, a wired power supply to the oscillation circuit. In this way, the power supply circuit can be galvanically decoupled from the oscillation circuit, at least if there is no wired power supply.

In some embodiments, the power supply circuit comprises a third switching device which is configured, depending on a control, to temporarily connect a second feed point for electrical energy to the oscillation circuit in order to supply the oscillation circuit with electrical energy supplied or supplyable at the second feed point in such a way that the polarity of a first electrical supply voltage applied to the first feed point is opposite to the polarity of a second electrical supply voltage applied at the same time to the second feed point, thus enabling a bipolar energy supply to the oscillation circuit.

The generation and/or feed of the second supply voltage can, in particular, correspond to the supply voltage supplied to the first feed point according to one or more of the embodiments described herein, and in particular (except for the different polarity) be identical thereto.

Combined Circuit with Step-Up Converter and Pausable Oscillation Circuit

The aforementioned principles of the first circuit and the second circuit can also be used in combination within the solution.

According to a first approach, such a combined circuit is obtained in particular by further providing, starting from the first circuit (in particular starting from one of its embodiments described herein), an oscillation circuit which comprises a capacitor which is at least partially defined by the MEMS capacitor, an oscillation circuit inductor and a controllable second switching device for selectively interrupting or closing the oscillation circuit as a function of a control of the second switching device. The oscillation circuit comprises a resonance frequency related to a permanently closed state of the oscillation circuit. In addition, the controller is further configured to control the second switching device such that it temporarily opens the second switching device for a specific portion of the oscillation period during a respective oscillation period of the oscillation circuit, in order to thereby cause an interruption of the oscillation circuit and thus an actual oscillation frequency of the oscillation circuit which is lower than the resonance frequency.

The circuit may in particular comprise any, in particular one or more of the embodiments of the second circuit described herein.

The electrical oscillations generated in the oscillation circuit thus lead to a time-varying, in particular alternating, charge and thus voltage of the MEMS capacitor, so that the mechanical variable for driving a movement of the actuator, to which the MEMS capacitor belongs, also varies accordingly.

According to a second approach, such a combined circuit also results in particular in that, starting from the second circuit with power supply circuit, this power supply circuit comprises a step-up converter which is configured to convert an input voltage applied to the feed point into a higher output voltage in order to supply the oscillation circuit with electrical energy using this output voltage when the second switching device is in a state in which it temporarily electrically connects the feed point to the oscillation circuit. In this way, a high-voltage source can be dispensed with and instead only a low-voltage source can be used to provide a supply voltage for the second circuit. The step-up converter may in particular comprise a step-up converter circuit according to the first circuit, wherein the oscillation circuit capacitor is formed at least partially by the MEMS capacitor of the step-up converter circuit.

The circuit can have, individually or equally, each, in particular one or more of the embodiments of the step-up converter circuit described herein from the first circuit as a step-up converter circuit, in particular in the case of more than one feed point.

### MEMS, in Particular a Microscanner System

A third aspect of the present solution relates to a MEMS including: (i) a mass element configured to oscillate; (ii) an actuator for driving an oscillating movement of the mass element; and (iii) a circuit according to the first aspect or the second aspect or a circuit combined thereof, in each case for controlling the actuator such that it is thereby caused to move the oscillatory mass element in an oscillating movement.

The MEMS capacitor is designed as a component of the actuator in such a way that it itself forms a component of an electromechanical converter of the actuator, and the converter is configured to convert electrical energy stored in the MEMS capacitor into at least one mechanical variable for driving a movement of the actuator in order to thereby drive the oscillating movement of the mass element.

In some embodiments, the MEMS comprises a microscanner system and the mass element is designed as an oscillatory deflection element of the microscanner system for deflecting electromagnetic radiation incident on the deflection element. This allows a particularly energy-efficient drive of the movement, in particular of the deflection element, in particular for scanning an electromagnetic beam (e.g., laser beam).

The features and advantages explained with respect to the first or second aspect of the solution also apply correspondingly to the microscanner system according to the third aspect of the solution.

Further advantages, features, and possible applications of the present invention result from the following more detailed description in conjunction with the figures.

In the figures:

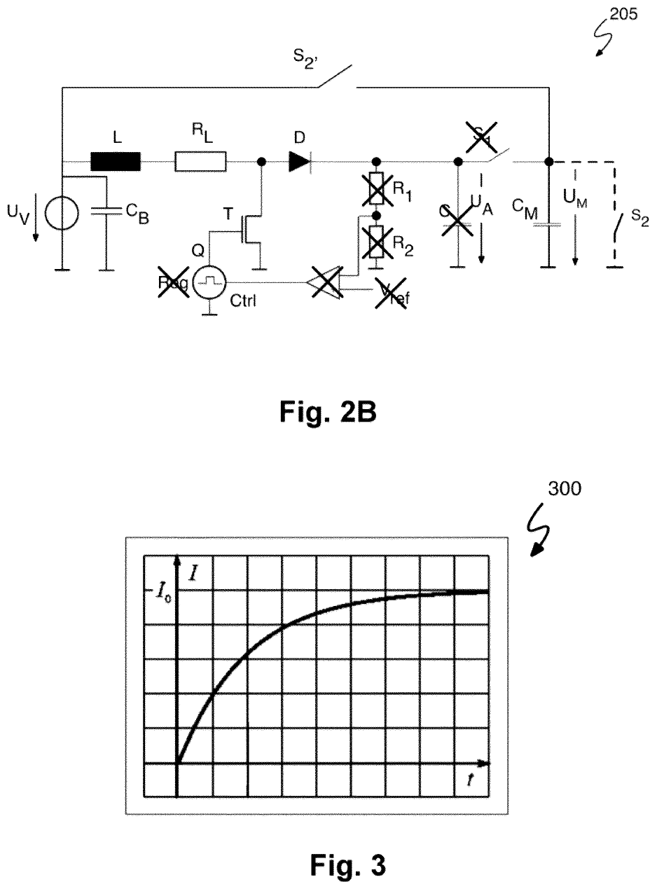

FIG. 1 as a starting point for the explanation of the first circuit from FIG. 2A, shows a conventional circuit for controlling a capacitive actuator with a regulated step-up converter;

FIG. 2A shows a first exemplary embodiment of the first circuit which enables unipolar control of the actuator;

FIG. 2B shows a comparison of the circuits of FIGS. 1 and 2A;

FIG. 3 shows a diagram showing a plot against time of a current through the inductor of the circuit of FIG. 2A/2B during its operation, while the magnetic energy is built up in the inductor;

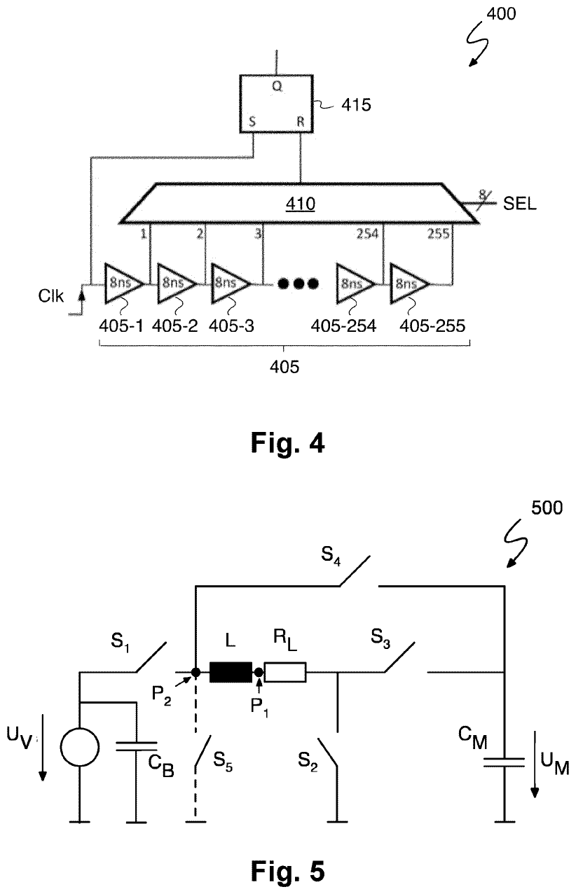

FIG. 4 shows an exemplary embodiment of a control device for controlling a first circuit, in particular according to FIG. 2A.

FIG. 5A shows a first exemplary embodiment of the first circuit which enables bipolar control of the actuator;

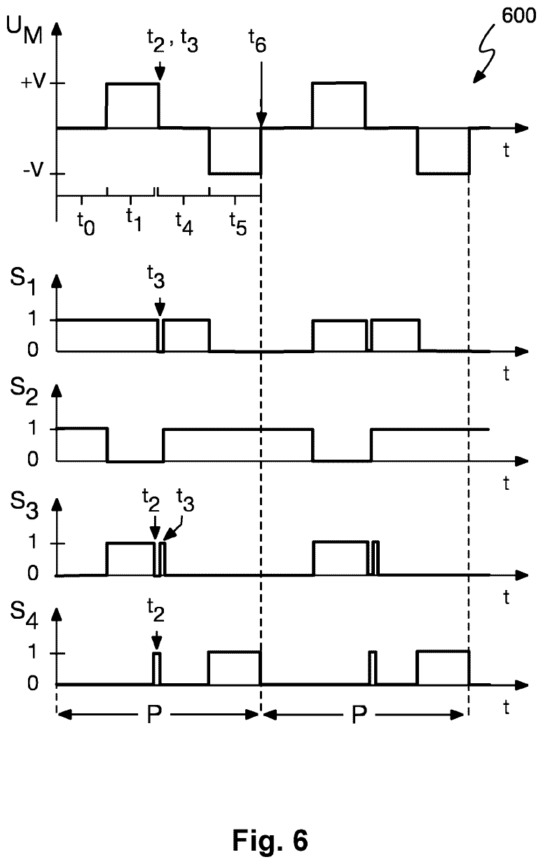

FIG. 6 shows an exemplary plot against time of the configuration of the switching device of the circuit from FIG. 5, in particular the switching states of its individual switches; and

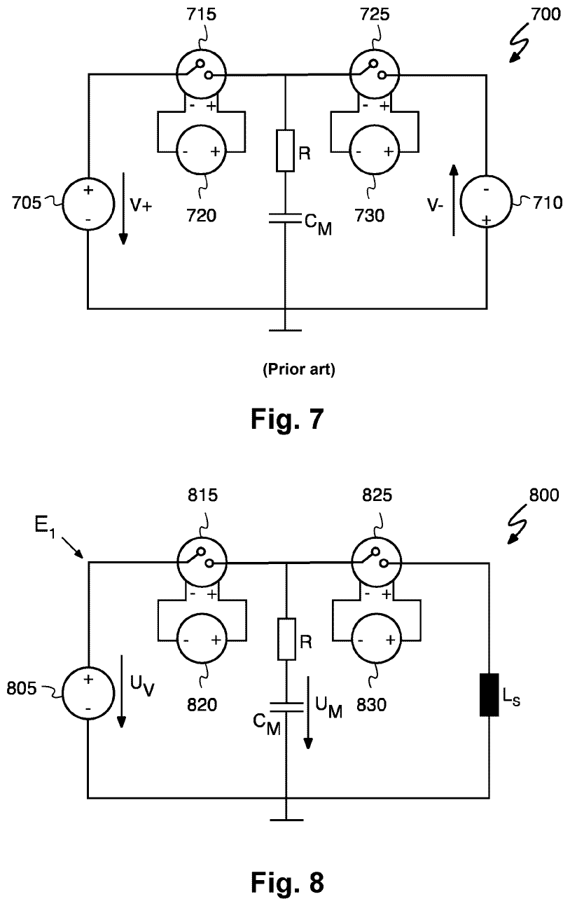

FIG. 7 as a starting point for the explanation of the second circuit from FIG. 8, shows a conventional circuit for controlling a MEMS actuator for driving an oscillating MEMS, in which a MEMS capacitor of the MEMS actuator is recharged by means of a half-bridge using two opposite-polarity supply voltages;

FIG. 8 shows a first exemplary embodiment of the second circuit, with a pausable oscillation circuit and with a high voltage source for providing a supply voltage for the circuit;

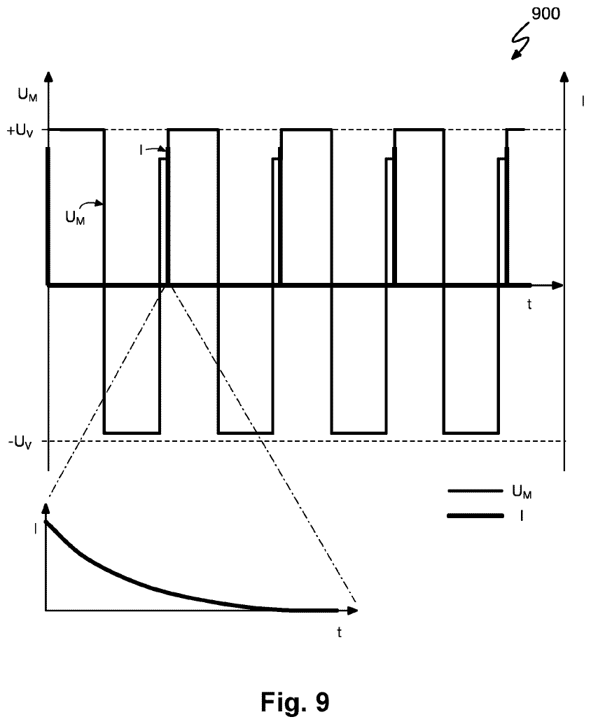

FIG. 9 shows a qualitative representation of the voltage curves at the MEMS capacitor of the oscillation circuit and the charging current to be supplied by the high-voltage source in the circuit of FIG. 8;

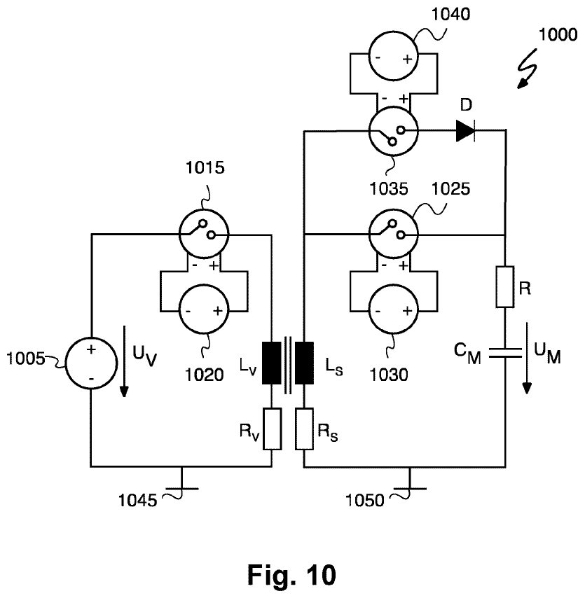

FIG. 10 shows a second exemplary embodiment of the second circuit with a pausable oscillation circuit and with a high-voltage source inductively coupled to the oscillation circuit via a coupled pair of coils for providing a supply voltage for the circuit;

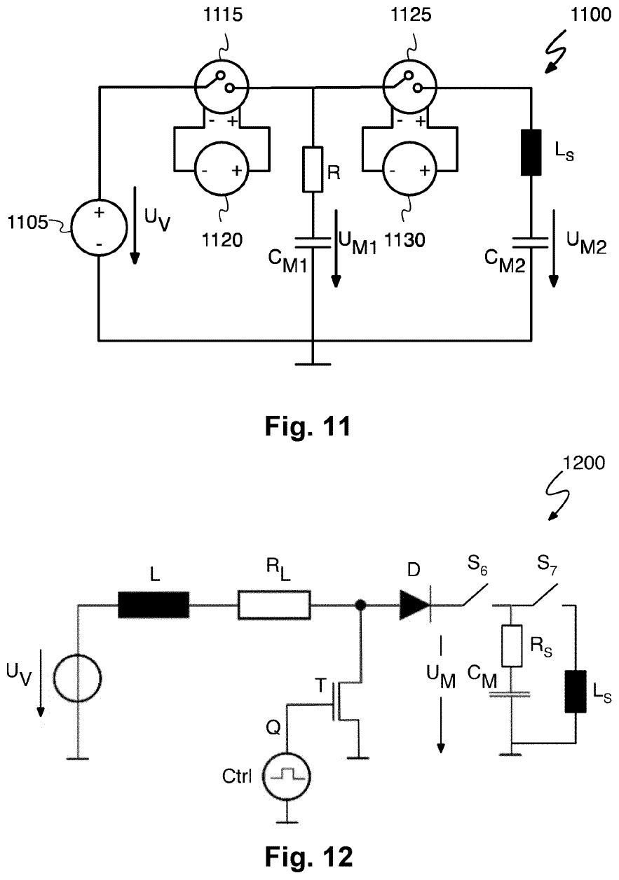

FIG. 11 shows a third exemplary embodiment of the second circuit with a pausable oscillation circuit and with an oscillation circuit capacitor divided between two separate MEMS capacitors;

FIG. 12 shows a first exemplary embodiment of a circuit in which the concepts of the first circuit and the second circuit are combined to form a circuit with a unipolar step-up converter and a pausable oscillation circuit;

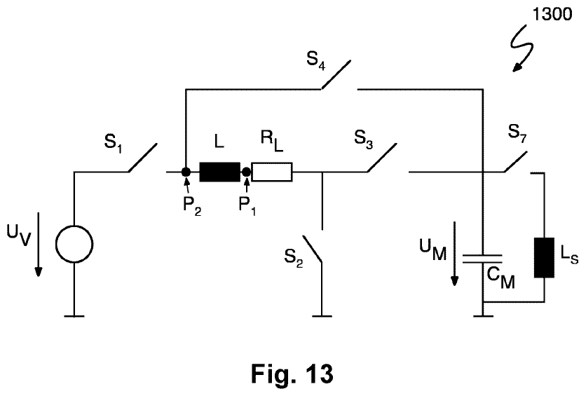

FIG. 13 shows a second exemplary (bipolar) embodiment of a circuit in which the concepts of the first circuit and the second circuit are combined to form a circuit with a bipolar step-up converter and a pausable oscillation circuit;

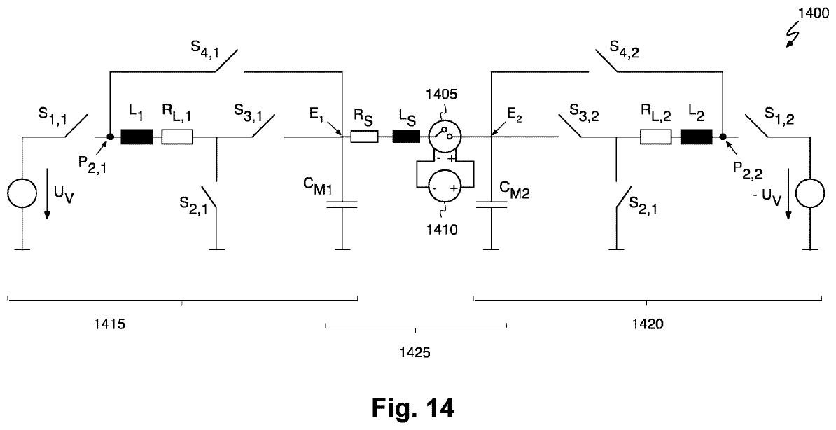

FIG. 14 shows a third exemplary (bipolar) embodiment of a circuit in which the concepts of the first circuit and the second circuit are combined to form a circuit for differential and bipolar control of a MEMS actuator.

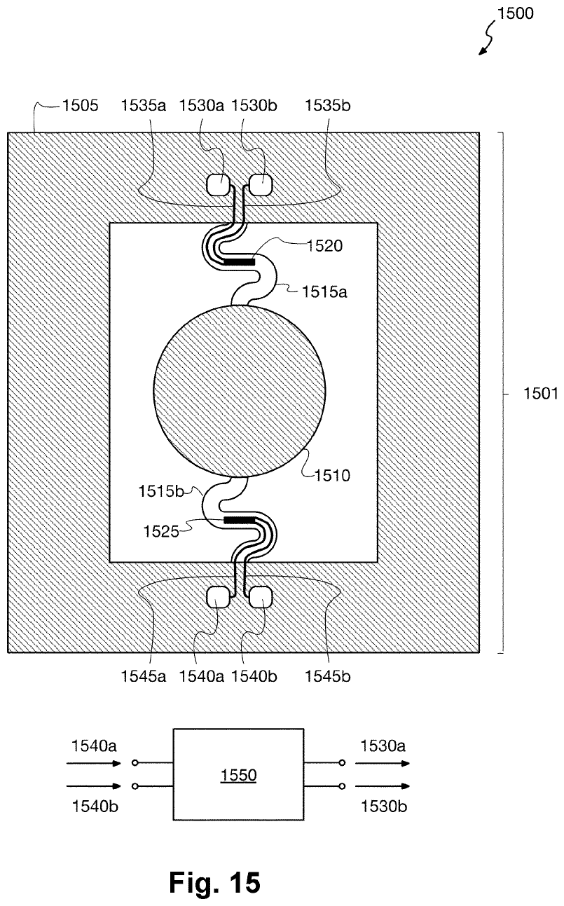

FIG. 15 shows an exemplary embodiment of a MEMS, here specifically as a microscanner.

In the figures, the same reference numerals regularly designate the same, similar, or corresponding elements (except in some cases when naming switching devices). Elements depicted in the figures are not necessarily represented to scale. Rather, the various elements shown in the figures are presented in such a way that their function and general purpose can be understood by those skilled in the art. Connections and couplings shown in the figures between functional units and elements can also be implemented as an indirect connection or coupling, unless expressly stated otherwise. The control or control device can be implemented in particular by means of hardware, software, or by means of a combination of hardware and software.

### Exemplary Embodiments of the First Circuit

The following are explanations of exemplary embodiments of the first circuit, starting with the conventional circuit 100 from FIG. 1:

The circuit 100 of FIG. 1 corresponds to a typical design of an asynchronous step-up converter (DC/DC converter) from the prior art and is explained here for reference purposes, in particular to identify important differences compared to circuits according to the solution.

A voltage source provides a supply voltage U_{V} as a direct voltage and thus feeds an inductor (coil) L when a circuit is closed by the inductors. The resistance R_{L} represents the ohmic resistance of the inductor in the sense of an equivalent circuit and is not relevant for the further discussion of the circuit(s).

In a first phase of the circuit's operation, the circuit is closed by the inductor L by turning the field-effect transistor T on. This is done via a regulator Reg which controls the transistor T accordingly via its gate. The current flow through the inductor L creates a magnetic field in which energy provided by the supply voltage U_{V} is stored (in the form of magnetic energy).

If in a second phase the transistor T is switched off by the regulator Reg, the inductor L tries to maintain its magnetic flux according to Lenz's law or the law of induction despite the interruption of the previous circuit by inducing a voltage so that the current generated thereby creates a magnetic field which counteracts the change in the magnetic flux. The induced voltage in particular causes the diode D to be switched in the forward direction above its threshold voltage and the current generated (at least proportionally in addition to the supply voltage U_{V}) from the magnetic field of the inductor L can flow into the buffer capacitor C, so that an output voltage U_{A} builds up there above the buffer capacitor C. The diode therefore acts like a switch.

The generation of the output voltage U_{A} is regulated, for which purpose a control loop with a voltage divider consisting of the resistors R₁ and R₂ and an operational amplifier OP is provided, the output of which is electrically connected to an input of the controller Reg to close the control loop. To control the regulator Reg, the voltage occurring at the center tap of the voltage divider is compared with a fixed reference voltage V_{ref} using the operational amplifier OP and, depending on the result of the comparison, a variable frequency or a variable duty cycle (alternative English terms are “duty factor” and “control degree”) of an output signal of the regulator Reg is determined, with which the transistor T is controlled. Thus, the closed-loop control allows the output voltage U_{A} at the buffer capacitor C to be set to a substantially constant value, which depends in particular on the reference voltage V_{ref}.

The output voltage U_{A} can now be used as a drive voltage to continuously switch an electrical connection to a MEMS actuator by closing a switch S₁ in order to drive it. As shown, the MEMS actuator can in particular have a MEMS capacitor C_{M} and in particular be a piezo actuator in which the MEMS capacitor C_{M} acts as a piezo element together with a piezo material arranged between its two different-pole electrodes. By means of a switch S₂ connected in parallel to the MEMS capacitor C_{M}, the MEMS capacitor C_{M} can be discharged again, in particular to 0V. By appropriately controlling the switches S₁ and S₂, an excitation frequency for the MEMS actuator can be set with which the MEMS capacitor C_{M} oscillates back and forth between a charged and an uncharged state and accordingly sets the MEMS actuator into an oscillating mechanical movement, which in turn can be used to drive a mechanical movement of another component. The switches S₁ and S₂ can also be implemented by transistors.

The high voltage that can be generated by the circuit 100 can in particular be up to 200 V at a frequency of up to 100 KHz, such that the switches S₁ and S₂ must then be designed accordingly as high-voltage switches. However, if the buffer capacitor C is charged with a constant voltage source for the supply voltage U_{V}, as is the case in circuit 100, the theoretical efficiency is a maximum of only 50% due to the feeding of the MEMS capacitor C_{M} from the buffer capacitor C and the resulting occurrence of the so-called “capacitor paradox.” The remaining part of the applied energy is lost, especially in the resistance of the (high-voltage) switch S₁, the ohmic resistance R_{L} of the coil, and the supply lines as power loss.

Typical properties of such a conventional circuit 100 are therefore:
low efficiency due to the capacitor paradox
permanent switching of the transistor T, to replenish the charge consumed on average for periodic recharging of the MEMS capacitor C_{M} (leads to higher overall power consumption due to switching losses and can also lead to noise in other circuit components)
relatively high power consumption due to the permanent regulation of the output voltage
large system volume (requires output voltage regulation and a high-voltage switch S₁, which leads to high regulation and switching losses)
high overall circuit complexity
requires analog components to ensure the closed-loop control stability of the step-up converter
requires a high-voltage switch S₁, which has to be constructed in a complex manner (e.g., bootstrap circuit or similar) and is therefore not energy efficient.

FIG. 2A, on the other hand, shows a first exemplary embodiment 200 of a first circuit with which one or more of the aforementioned disadvantages can be reduced or even avoided. FIG. 2B illustrates in the context of a comparison 205 of the circuits 100 and 200 which circuit components can be saved in the circuit 200.

In contrast to circuit 100, the transistor T is no longer controlled by a regulator (closed-loop) but by a controller (open-loop) Ctrl by means of a control signal Q, and the charging current does not flow into a buffer capacitor C, from which the MEMS capacitor C_{M} is then subsequently charged, but instead flows directly without capacitive buffering into the MEMS capacitor C_{M} of the actuator, in particular MEMS actuator, in order to build up a drive voltage U_{M} across the MEMS capacitor C_{M}.

The MEMS capacitor C_{M} is designed as a component of an actuator in such a way that it forms a component of an electromechanical converter of the actuator, wherein the converter is configured to convert electrical energy stored in the MEMS capacitor C_{M} into at least one mechanical variable for driving a movement of the actuator (in particular at least one component thereof). The actuator can in particular be a piezo actuator or piezo element in which a piezoelectric material is arranged between the electrodes of the MEMS capacitor C_{M} such that, when an electrical voltage U_{M} occurs between the electrodes, it lies in the associated electric field and deforms according to the inverse piezo effect, whereby electrical energy is converted into mechanical energy.

The circuit 200 comprises a switching device which comprises the transistor T, the diode D and the switch S₂. Optionally, the further switch S₂ already known from FIG. 1 can be present in order to be able to discharge the MEMS capacitor C_{M} directly to ground, in particular after energy recovery into a supply-side buffer capacitor C_{B}. Assuming that the supply voltage is x, e.g., 3V, then an additional voltage change across the MEMS capacitor C_{M} increased by x could be generated using the switch S₂. However, the switch S₂ should only be closed for a short time to avoid “charging” of the inductor L by a current fed from the supply voltage U_{V}. Alternatively, the supply voltage U_{V} can be decoupled from the inductor L during the discharge of the MEMS capacitor C_{M} by means of an optional additional switch (not shown).

As can be seen particularly with respect to FIG. 2B, the circuit 200 has a significantly lower complexity compared to the circuit 100 with a significantly higher efficiency, in particular due to the avoidance of the (high-voltage) switch S₁, the buffer capacitor C and the associated capacitor paradox as well as the control including the associated control loop with the voltage divider R₁, R₂, the operational amplifier OP, the regulator Reg and its switching frequency generation function for the transistor T.

The mode of operation of the circuit in FIG. 2A/2B can be described as follows:

If the transistor T is switched on by means of a corresponding control by the control Ctrl (“first” circuit configuration), a first current path through the inductor L is switched on in order to cause an increasing current flow through the inductor L fed by the supply voltage U_{V}. In this case, the current through the inductor L increases (initially approximately linearly). The resistance R_{L} should represent (in the sense of an equivalent circuit diagram) the winding resistance of the inductor L (coil).

After the time t, the transistor T is switched off (“second” circuit configuration), so that a capacitor-unbuffered second current path between a first pole of the inductor L and the MEMS capacitor C_{M} is continuously switched, via which the MEMS capacitor C_{M} is charged directly by means of a current flow fed at least partially by the inductor L through the diode D which is then charged to a first voltage which is equal to or higher than the supply voltage U_{V}. In this process, the magnetic energy stored in the inductor L is dissipated and directly converted into the electrical energy building up in the MEMS capacitor C_{M}.

If we consider the plot against time 300 of the current flowing through the inductor L during the first circuit configuration, this can be indicated by the following relationship, as illustrated in FIG. 3:

$$I ( t ) = {I}_{0} ( 1 - {e}^{- \frac{R}{L} t} ) \qquad ( 2 )$$

Here, R corresponds to the sum of the parasitic series resistances of the inductor L and the path resistance of the switched-on transistor T (the intermediate paths are idealized here as having only a negligible resistance) and U_{V} is again the supply voltage, which at the same time corresponds to the voltage drop across this series circuit. I₀ is a maximum current (limit current) to which the charging current I(t) approaches asymptotically over time. The limit current is calculated as:

$${I}_{0} = \frac{{U}_{V}}{R} \qquad ( 3 )$$

To simplify equation (2), it can be linearized at the origin at time t=0 by its derivative:

$$\frac{dI ( t )}{dt} = \frac{{I}_{0} R}{L} {e}^{- \frac{R}{L} t} \qquad ( 4 )$$

At time t=0, this relationship simplifies to:

$$\frac{dI ( 0 )}{dt} = \frac{{I}_{0} R}{L} \qquad ( 5 )$$

By inserting (3) into (5), the linearization at time t_{L} at which the switch to the second circuit configuration occurs results for the current I by the inductor:

$$I ( {t}_{L} ) \approx \frac{{U}_{V}}{L} {t}_{L} \qquad ( 6 )$$

The stored energy Ein the inductor L at time t=t_{L} is:

$${E}_{L} ( {t}_{L} ) = \frac{1}{2} {LI}^{2} ( {t}_{L} ) \qquad ( 7 )$$

Correspondingly, the energyE_{M} of the MEMS capacitor C_{M}, wherein U_{M} is the capacitor voltage across C_{M}, is:

$${E}_{M} = \frac{1}{2} {C}_{M} {U}_{M}^{2} \qquad ( 8 )$$

If we equate the two equations (7) and (8) and replace I(t_{L}) by the expression from equation (6), the voltage U_{M} to which the MEMS capacitor C_{M} is charged due to the energy transfer from the inductor L is:

$${U}_{M} \approx \sqrt{\frac{1}{{LC}_{M}}} {U}_{V} {t}_{L} \qquad ( 9 )$$

Thus, the voltage U_{M} across the MEMS capacitor C_{M} scales to a good approximation proportional to the time period in which the transistor is switched on, also proportional to the supply voltage U_{V}, and in square root form with the inverse of values for the inductor L and the MEMS capacitor C_{M}. This approximation is particularly valid when the sum of all parasitic resistances (e.g., series resistance of the coil, series resistance of the MEMS capacitor C_{M}, and track resistances) is comparatively small in absolute terms. Otherwise, these ultimately led to a lower charging voltage of the MEMS capacitor C_{M}, since the energy stored in the coil is not only transferred to the MEMS capacitor, but is also in part converted into heat.

The voltage U_{M} across the MEMS capacitor C_{M} can thus be considered, at least approximately, as a linear function of the time period ty. Since all components within the circuit, in particular L and C_{M}, are known, the output voltage U_{M} can be adjusted solely via the controllable switch-on time t_{L} of the transistor T. This allows the regulator Reg to be eliminated, which leads to a significant simplification of the circuit 200 compared to the conventional circuit 100.

The switch S₂ for discharging the MEMS capacitor C_{M} can either be connected in parallel to C_{M} as shown in FIG. 1 (third current path) or, as shown, connected in a fourth current path leading back to the supply voltage source (then referred to as switch S₂ to indicate this different arrangement). The supply voltage source (but not the second current path between inductor and MEMS capacitor C_{M}) is buffered by a buffer capacitor C_{B}, in which the charges flowing back via switch S_{2′} when discharging C_{M} are temporarily stored and can be reused for a further activation cycle of the actuator. This allows to increase the efficiency of the circuit 200 further. FIG. 4 shows an exemplary embodiment 400 of the control device Ctrl for controlling a circuit according to the solution, in particular according to FIG. 2A. It serves to control the switch-on time or switch-on duration of the transistor T and thus also the output voltage U_{M} and is implemented with a delay chain 405 with several delay elements 405-1, . . . , 405-n connected in series, a multiplexer 410, and a flip-flop.

In this example, n=255 is chosen. The delay elements 405-1, . . . , 405-255 can be designed from standard cells or customized, particularly application-specific, in analog circuit technology. The required delay time of each individual delay element can be calculated from the quotient of the maximum required switch-on time and the number of delay elements. In the example, for the sake of simplicity, the same delay time of 8 ns was chosen for all delay elements 405-1, . . . , 405-255.

An analog design has the particular advantage that the delay time of each individual delay element can be individually adjusted via a current control and can therefore be optimally adjusted for any MEMS capacitors (with different capacitor values and output voltages).

Each clock pulse of a clock signal CLK applied to the control device 400 is thus divided evenly according to the number of delay elements 405-1, . . . , 405-255.

By applying a selection signal SEL to the multiplexer 410, the desired stage of the delay chain can be selected, which is output to the R input of the RS flip-flop 415. When the clock signal CLK is at level “1” or “high,” the output signal Q (e.g., with level “1”) switches on the transistor T. However, as soon as the output signal of the multiplexer 410 subsequently changes (e.g., to the level “1”) according to the selected delay, the output signal Q changes (e.g., to the level “0”) in such a way that the transistor T is blocked. By selecting the delay using the selection signal SEL, the time period ty during which the inductor L is “charged” with magnetic energy can be set. Since the level of the voltage U_{M} across MEMS capacitor C_{M} in turn depends on the time period t_{L}, the level of the voltage U_{M} and thus the activity of the actuator can be controlled by means of the selection signal SEL.

FIG. 5 shows a circuit 500 for bipolar control of an actuator with a controlled step-up converter as a second exemplary embodiment.

In the circuit 500, which represents a modification or further development of the circuit 200, the switching device is further configured to repeatedly and temporarily in each case during a period in which the second current path located between a first pole of the inductor L and the MEMS capacitor C_{M} is not continuously connected, to continuously connect a fourth current path between the MEMS capacitor and a second pole P₂ of the inductor L, which is electrically opposite in polarity to the first pole P₁, such that the MEMS capacitor C_{M} is charged to a second voltage with a polarity opposite to the polarity of the first voltage.

For this purpose, the switching device of the circuit 500 has four switches S₁ to S₄. The switch S₁ is located in the current path between the supply voltage U_{V} and the second pole P₂ of the inductor L. The switch S₂ is located in the first current path between the first pole P₁ of the inductor L and ground. In particular, it can be realized, as shown in FIG. 2A, by a transistor T (or multiple transistors and/or diodes). The same applies to all other switches. The third switch S₃ is located in the second current path between the first pole P₁ of the inductor L and the MEMS capacitor C_{M}. The fourth switch S₄ is located in a further (“fourth”) current path between the MEMS capacitor C_{M} and the supply voltage U_{V} or its buffer capacitor C_{B} and corresponds to the switch S_{2′} from FIG. 2B.

Optionally, another switch S₅ can be provided between the second pole P₂ and ground.

The functioning of the circuit 500 is illustrated in FIG. 6 using the plot against time 600 of the configuration of the switching device of the circuit 500, in particular the switching states of its individual switches S₁ to S₄.

The switching states of the switching device are gradually set into different switching states by a controller (not shown) over time according to the following sequence with the successive time intervals t₀ to t₆, wherein “1” indicates a closed switch and “0” an open switch in the diagrams and the sequence is run through at least once:

| Time | | | | | |
|---|---|---|---|---|---|
| interval | U_{M} | S₁ | S₂ | S₃ | S₄ |
| before t₀ | Idle | 0 | 0 | 0 | 0 |
| t₀ | 0 | 1 | 1 | 0 | 0 |
| | (Coil charging | | | | |
| | process) | | | | |
| t₁ | +V | 1 | 0 | 1 | 0 |
| | Idle | 0 | 0 | 0 | 0 |
| t₂ | +V [symbol] +V₁ | 1 | 0 | 0 | 1 |
| t₃ | +V₁ [symbol] 0 | 0 | 1 | 1 | 0 |
| | Idle | 0 | 0 | 0 | 0 |
| t₄ | 0 | 1 | 1 | 0 | 0 |
| | (Coil charging | | | | |
| | process) | | | | |
| t₅ | −V | 0 | 1 | 0 | 1 |
| | Idle | 0 | 0 | 0 | 0 |
| t₆ | −V [symbol] 0 | 0 | 1 | 1 | 0 |

FIG. 6 shows a special case where this sequence is repeated periodically (the transitions between the successive periods P are marked by vertical dashed lines). As shown in the table (but not illustrated in FIG. 6), after each charging or discharging of the MEMS capacitor C_{M} until a point in time at which the inductor L has to be charged again, an idle state is established in which all switches are open (“idle” state) and the MEMS capacitor C_{M} is “floating”, i.e., it does not have a defined electrical potential itself due to the lack of connection to a defined electrical potential. This serves to prevent the charge stored in the MEMS capacitor C_{M} during charging from flowing off again, in particular towards the supply source, or to prevent the just discharged MEMS capacitor C_{M} from immediately being (partially) charged again. Conversely, this also means that the control device should be designed in such a way that the relevant switch(es) (e.g., S₃) is/are opened immediately as soon as the energy of the coil has been completely used up. Alternatively, this function can be taken over by a corresponding design of the switch itself.

Before the time interval to, all switches are open (“idle” state) and the MEMS capacitor C_{M} therefore has no defined electrical potential (is floating). In the time interval to, the “first” circuit configuration is present, in which only the switches S₁ and S₂ are closed, such that the first current path through the inductor L is closed and, due to a current fed by the supply voltage U_{V} along the first current path in the inductor L, a magnetic field with the associated magnetic energy is built up. The coil is thus “charged” with energy.

During the transition to the subsequent time interval t₁, while switch S₁ remains closed, switch S₂ is opened and switch S₃ is closed instead, such that a “second” circuit configuration is then present in which the second current path is continuously switched from a first pole of the inductor L via the closed switch S₃ to the MEMS capacitor C_{M}, such that the magnetic energy stored in the inductor L in the meantime causes a current flow along the second current path, by means of which the MEMS capacitor C_{M} is charged to the positive voltage U_{M}=+V.

This is followed by an idle state (not illustrated in FIG. 6) in which all switches are open to prevent the charge now stored in the MEMS capacitor C_{M} from flowing back to the voltage source for the supply voltage U_{V}.

In the subsequent time interval t₂ (which is optional), the switch S₃ is opened again and instead the switch S₄ is closed, such that a further current path is continuously switched via the switch S₄ (corresponds in particular to the claimed “fourth” current path), via which the MEMS capacitor C_{M} is at least partially discharged into the buffer capacitor C_{B} (for buffering the supply voltage U_{V}) to a lower voltage U_{M}=+V₁. Thus, “charge recycling” can be carried out in the sense that part of the charge of the buffer capacitor C_{B} can be reused for the next build-up of a magnetic field in the inductor L, and thus the efficiency of the circuit 500 can be increased.

Alternatively, by closing switches S₂ and S₄ while switches S₁ and S₃ are open, charge recovery from the MEMS capacitor C_{M} can be used directly by causing a corresponding current through the inductor L to build up magnetic energy in the inductor L (not illustrated).

In the time interval t₃, only the switches S₂ and S₃ are closed, such that the MEMS capacitor C_{M} can be completely discharged to ground (this step can be omitted in the aforementioned alternative, since the MEMS capacitor C_{M} is already discharged there in the time interval t₂).

This is followed by an “idle state” (not illustrated in FIG. 6) in which all switches are open to prevent the MEMS capacitor C_{M} from being (partially) charged again in an uncontrolled manner.

During the subsequent time interval t₄, only the switches S₁ and S₂ are closed, so that the inductor is charged with magnetic energy via the first current path, as in the time interval to. The current flow through the inductor L is fed from the supply voltage U_{V} and partly from the buffer capacitor C_{B}.

In the time interval t₅, while switch S₂ remains closed, switch S₁ is opened and switch S₄ is closed, such that charge flows from the MEMS capacitor C_{M} via S₄ through the inductor L and via S₂, wherein due to the inductor L's tendency to maintain the original current flow through it (Lenz's law), the current flow continues until the MEMS capacitor C_{M} is charged to a negative voltage value, which in terms of magnitude can correspond in particular to the positive voltage value +V and thus be −V.

This is again followed by an idle state (not illustrated in FIG. 6) in which all switches are open to prevent the charge now stored in the MEMS capacitor C_{M} from flowing back to the voltage source for the supply voltage U_{V}.

Finally, in the time interval to only the switches S₂ and S₃ are closed again, such that the MEMS capacitor C_{M} can be completely discharged to ground to 0V. Then a new cycle can be started with another run through the sequence.

The optional switch S₅ can be used in particular as follows to be able to recover charges at negative voltages, analogous to the charge recovery at positive voltages described above: If the MEMS capacitor C_{M} is to be discharged from −V to 0, for example, S₅ and S₃ can be closed. Now a current builds up again in the inductor L.

If the MEMS capacitor C_{M} is empty, S₅ and S₃ can be opened immediately and S₁ and S₂ can be closed instead to allow the current in the inductor L to continue to increase. Then everything continues as described above.

### Exemplary Embodiments of the Second Circuit

The following are explanations of exemplary embodiments of the first circuit, starting with the conventional circuit 700 from FIG. 7:

The circuit 700 of FIG. 7 represents a so-called half-bridge circuit. It has two supply voltage sources 705 and 710, which provide complementary voltages. The central circuit branch of the circuit 700 has a component to be driven by means of the half-bridge circuit, in the present example a capacitive MEMS actuator, such as a piezo actuator. The MEMS capacitor of the MEMS actuator is denoted here as C_{M}. An ohmic resistance of the central circuit branch that occurs in reality is represented, here in the sense of an equivalent circuit diagram, by the resistance R, which, however, plays no role in the further explanations.

Furthermore, the circuit has two switching devices 715 and 725, which can each be controlled by an associated control voltage source 720 or 730 of variable control voltage, such that depending on this respective control voltage, the switching device (e.g., switch or switching transistor) 715 or 725 associated therewith continuously switches or interrupts a current path between the associated supply voltage source 705 or 715 and the MEMS capacitor C_{M}. By alternately temporarily switching the two current paths through the switching devices 715 and 725, the MEMS capacitor C_{M} can be alternately recharged to a positive or a negative voltage V+ or V−, whereby the MEMS actuator can execute or drive a corresponding alternating movement.

However, this type of circuit is not very energy efficient. On average, the circuit 700 must operate with the total power

$${P}_{total} = {C}_{M} \cdot {U}^{2} \cdot f \qquad ( 10 )$$

applied by the supply voltage sources 705 and 710.

Here, C_{M} describes the capacitor value of the MEMS capacitor, U the peak-to-peak voltage across the MEMS capacitor, and f the frequency of the resulting square wave voltage. In the example of a microscanner as a MEMS with a typical MEMS capacitor of its actuator to drive the deflection element of 100 pF, a voltage swing of 200 V (+100 V), and a frequency of 25 kHz, this would result in a theoretical power consumption of 100 mW.

A first reason for the rather low energy efficiency of the circuit 700 is that, due to the so-called “capacitor paradox” or “two-capacitor paradox” (see https://en.wikipedia.org/wiki/Two_capacitor_paradox) occurring here and which is known in general in circuit design, at least 50% of the absorbed power is converted directly into heat when charging or recharging the MEMS capacitor C_{M}. This is also the case when the line resistance (but also R, for example) becomes infinitesimally small.

A second reason is that the remaining portion of the supplied power is required for building up the different energy levels in the MEMS capacitor C_{M}, i.e., for the alternating recharging, wherein, however, charge flowing out of the MEMS capacitor C_{M} during recharging is diverted to ground or through the voltage sources without being recovered for further use.

FIG. 8 shows a first exemplary embodiment 800 of the second circuit, which enables bipolar control of the actuator, more precisely of the MEMS capacitor C_{M}. In this case, however, a single supply voltage source 805 is sufficient, which in its construction can correspond in particular to the supply voltage source 705 and supplies a DC voltage as the supply voltage U_{V} of the circuit 800, in particular at a feed point E₁. Typically, given the voltage requirements of the actuator, this is a high-voltage source (in the present context, a voltage source that can provide a supply voltage that is higher than the typical supply voltages of logic circuits, in particular semiconductor circuits). The supply voltage can be greater than 10 V in particular, and in particular can be at or above 100 V.

Instead of the second supply voltage source 710, the circuit 800 contains an inductor L_{S} (“oscillation circuit inductor”), which together with the MEMS capacitor C_{M} (and R) and a switching device 825 forms an oscillation circuit. The switching device 825 can in particular correspond in its construction to one of the switching devices 715 and 725 described above. The oscillation circuit can be electrically connected via a switching device 815 to the feed point E₁ fed by the supply voltage source 805 in order to transfer electrical energy from the supply voltage source 805 into the oscillation circuit when the switching device 815 is closed.

If the switching device 825 were not present or permanently closed, then the oscillation frequency of the oscillation circuit would be given by its resonance frequency f₀, which is determined by the values of C_{M} and L_{S} according to relationship (1) (see above).

Especially in the case of microscanners, typical resonance frequencies of deflection elements (mirror plates) are in the range of up to a maximum of 100 kHz. The capacitor of the piezoelectric material is typically in the range up to approximately 150 pF. First and foremost, one could now choose a coil with a suitable inductor value as the oscillation circuit inductor L_{S}, such that the resonant frequency f₀ of the electrical oscillation circuit corresponds exactly to the resonant frequency of the deflection element.

However, it turns out that according to the relationship (1), solved for L, impractically large inductor values result:

$${L}_{s} = \frac{1}{{( 2 π {f}_{0} )}^{2} \cdot {C}_{M}} = \frac{1}{{( 2 π \cdot 100 kHz )}^{2} \cdot 150 pF} = 16.9 mH$$

However, such large inductor values for L_{S} in combination with small winding resistances would be very space-consuming and therefore unfavorable in products where the smallest possible design of the MEMS is important, such as in AR/VR glasses. The smaller the resonance frequency f₀ and/or the value for C_{M} is specified, the larger the required inductor L_{S} becomes. At f₀=30 KHz and C_{M}=100 pF, L_{S} would already have a value of almost 300 mH.

If L_{S} has to be kept small, especially for space reasons, a circuit implementation with a classic, permanently closed oscillation circuit is therefore unfavorable or even impossible.

As illustrated in FIG. 9 using the current and voltage curves 900 at the MEMS capacitor C_{M}, the operation of the circuit 800 can therefore take place in particular as follows, wherein a controller (not shown), such as a computer program-controlled microcontroller or a hard-wired control circuit, is used to control the switching devices: First, with the switching device 815 closed and the switching device 825 simultaneously open, a current path from the supply voltage source 805 via the initially uncharged MEMS capacitor C_{M} is switched continuously in order to charge the MEMS capacitor C_{M} for the first time to a voltage level +V by means of a charging current I from the supply voltage source 805. With sufficient charging time, the voltage across the MEMS capacitor C_{M} rises to the level of the supply voltage +V=U_{V} (see detail in FIG. 9). The oscillation circuit is now supplied with energy and begins to oscillate in the sense of an attenuated oscillation after the switching device 815 is opened and the switching device 825 is closed. However, this oscillation is modulated and thus changed towards a lower oscillation frequency in that in each oscillation period the switching device 825 is opened for a certain time portion of the oscillation period when the voltage U_{M} across the MEMS capacitor C_{M} just reaches a maximum and thus the energy present in the oscillation circuit, oscillating back and forth between C_{M} and L_{S}, is momentarily, at least largely, stored as electrical energy in C_{M}. In particular, the time component of the oscillation period can be about 50%, i.e., approximately half the period duration. To be more precise, it would be 50% minus the time the oscillation circuit needs to transfer between two voltage levels.

Meanwhile, energy lost to the oscillation circuit, particularly at the resistor R and the lines due to, in particular, ohmic losses (hence attenuated oscillation), can now be compensated by regularly temporarily closing the switching device 815 and opening the switching device 825 by recharging C_{M} with a temporary charging current I. This recharging preferably occurs when the voltage U_{M} across the MEMS capacitor C_{M} just reaches its maximum value in the current oscillation period. However, this does not necessarily have to happen in every oscillation period or after every recharging. Instead, it is also possible to carry out recharging only after several recharging cycles or only after several oscillation periods, e.g., every m-th time, with m EN, e.g., with m=2.

Recharging can generally take place with a positively polarized high-voltage source at times when the oscillation circuit is paused and the voltage across the MEMS is at its maximum, as well as with a negatively polarized high-voltage source at times when the oscillation circuit is paused and the voltage across the MEMS capacitor C_{M} is at its minimum. In this case, a somewhat more uniform voltage signal results across the MEMS capacitor C_{M}.

The oscillation circuit is thus regularly paused in order, on the one hand, to maintain its oscillation frequency f_{S}, which is reduced compared to the resonance frequency f₀ of the oscillation circuit (in the permanently closed case) determined by the values of C_{M} and L_{S} according to relationship (1) (see above), and, on the other hand, to recharge the energy lost during the electrical oscillation.

A significant advantage of this circuit is that due to the direct injection of the supply voltage U_{V} into the MEMS capacitor C_{M}, the adverse effect of the capacitor paradox can be reduced based on the principle of stepped, particularly adiabatic, charging and conduction losses can be reduced. In addition, the charges flowing during the recharging of C_{M} no longer have to be simply diverted to ground, but they remain available for the continued electrical oscillation in the oscillation circuit. In this way, a higher efficiency and thus a higher energy efficiency can be achieved than with the circuit 700 from FIG. 7.

In addition, the values of C_{M} and L_{S} can be chosen smaller than would be necessary in the case of a classical oscillation circuit to achieve the desired oscillation frequency f_{S}. This allows particularly space-saving circuit implementations to be achieved and also eliminates dependencies on component tolerances.

FIG. 10 shows a second exemplary embodiment 1000 of the second circuit with a pausable oscillation circuit and with a high-voltage source 1005 inductively coupled to the oscillation circuit via a coupled pair of coils for providing a supply voltage U_{V} for the circuit 1000. The voltage source 1005 can alternatively be a low voltage source, depending on the winding ratio of the coil pair.

Specifically, the circuit 1000 comprises two galvanically decoupled circuit parts, preferably including decoupled first and second masses 1045 and 1050, which are inductively coupled via a coil pair consisting of a first coupling coil L_{V} and a second coupling coil L_{S}. The second coupling coil L_{S} also represents the oscillation circuit inductor of the oscillation circuit. The coupling coils also each have an ohmic resistance R_{V} or R_{S}, which is shown here in the sense of an equivalent circuit diagram.

The first circuit part has a circuit loop which, in addition to the high voltage source 1005 and the first coupling coil L_{V} (with R_{V}), also contains a first switching device 1015 with an associated control voltage source 1020 for its time-variable control. Depending on the current switching state of the switching device 1015, the loop and thus the current path through the first coupling coil L_{V} is closed or interrupted, such that the inductive effect of the first coupling coil L_{V} and thus an inductive energy transfer to the second coupling coil L_{S} in the oscillation circuit can be controlled via the control voltage source 1020.

In addition to the second coupling coil L_{S} provided as an oscillation circuit inductor, the oscillation circuit again has the MEMS capacitor C_{M} of a MEMS actuator to be controlled (along with its ohmic resistance R) as well as a second switching device 1025 with an associated control voltage source 1030 for its time-variable control. Corresponding to the switching device 825 of FIG. 8, the oscillation circuit can be paused with the second switching device 1025.

In addition, the oscillation circuit also has a circuit branch connected in parallel to the second switching device 1025 with a diode D and a third second switching device 1035 with an associated control voltage source 1040 for its time-variable control.

If the switching devices 1015 and 1035 are open so that they interrupt the current paths passing through them, while the switching device 1025 is closed, the oscillation circuit is closed and “oscillates.” However, if the energy losses occurring in this process are to be compensated for (see FIG. 9), the switching devices 1015 and 1035 are closed and the switching device 1025 is opened.

Now, by means of a single current pulse (or by means of multiple successive current pulses with corresponding multiple closing and opening of the switching device 1015), a time-variable current, in particular alternating current, can be generated through the first coupling coil L_{V}, which current, by means of inductive energy transfer via the coil pair, causes an induction current in the second circuit part, which current runs via the switching device 1035 and is rectified via the diode D. Thus, the MEMS capacitor C_{M} can be recharged with direct current (which can be time-variable). This occurs during a period of time in which the voltage U_{M} across the MEMS capacitor C_{M} resulting from the previous oscillation in the oscillation circuit is at a maximum and has the same polarity as the induction voltage generated in the second coupling coil L_{S}. If the direction of the diode is reversed, it is possible to “recharge” the oscillation circuit when the voltage across the MEMS capacitor is right at its minimum. An additional current path also provides the option of bipolar recharging.

Instead of the DC voltage source 1005, an AC voltage source can likewise be used, so that the generation of DC pulses for generating a time-varying current through the first coupling coil L_{V} can be omitted.

FIG. 11 illustrates a third exemplary embodiment 1100 of the second circuit with a pausable oscillation circuit, which emerges from the circuit 800 of FIG. 8 by dividing the single oscillation circuit capacitor and at the same time the MEMS capacitor C_{M} into two separate MEMS capacitors C_{M1} and C_{M2}. In circuit 1100, for comparison with circuit 800, the supply voltage source 1105 corresponds to the supply voltage source 805, and the switching devices 1115 and 1125 (with associated control voltage sources 1120, 1130) correspond to the switching devices 815 and 825 (with associated control voltage sources 820 and 830), respectively.

Due to the division of the oscillation circuit capacitor between the two separate MEMS capacitors C_{M1} and C_{M2} in the arrangement shown, in which the oscillation circuit inductor LS and the switching device 1125 are connected between the two MEMS capacitors C_{M1} and C_{M2}, voltages U_{M1} and U_{M2}, respectively, arise at the MEMS capacitors C_{M1} and C_{M2} during the (pausable) oscillation of the oscillation circuit, which are phase-shifted with respect to one another and can have the same amplitude, especially if they have the same capacitor values. In particular, the MEMS capacitors C_{M1} and C_{M2} can be part of the same MEMS actuator, enabling a differential drive. For example, the MEMS capacitors C_{M1} and C_{M2} can each be configured as part of a piezo actuator in such a way that they cause piezoelectric forces acting in opposite directions, in particular by 180°, out of phase.

### Exemplary Embodiments for a Combination of First Circuit and Second Circuit

As already mentioned, the previously introduced circuit types “first circuit” and “second circuit” can also be advantageously combined. While the first circuit in particular allows the high voltages required for the operation of actuators, in particular MEMS actuators, to be provided even without using a high-voltage source as such, and instead using a low-voltage source, which can in particular be provided by a primary battery or secondary battery of a mobile device, the second circuit in particular allows a space-saving design of the circuit. In addition, both circuits serve to increase energy efficiency.

FIG. 12 illustrates a first exemplary embodiment 1200 of such a combined circuit for controlling an actuator, in particular a MEMS actuator, for driving an oscillating movement in a MEMS.

The circuit 1200 can be regarded as a further development or variant of the first circuit from FIG. 2A, so that only the differences will be discussed below.

A key difference is that, in accordance with the concept of the second circuit, the circuit 1200 comprises a pausable oscillation circuit with the MEMS capacitor C_{M} as the oscillation circuit capacitor. The oscillation circuit also contains an oscillation circuit inductor L_{S} and a switching device S₇ for temporarily interrupting (pausing) the oscillation circuit.

To recharge the MEMS capacitor C_{M}, when it has reached its maximum voltage value within the current oscillation period, the oscillation circuit is interrupted (paused) by means of the switching device S₇ and, by closing the further switching device S₆, a current path is closed between the step-up converter circuit shown in the left part of FIG. 12 and the oscillation circuit, in particular the MEMS capacitor C_{M}.

The oscillation circuit can therefore be supplied with energy solely by means of a low-voltage source to provide the supply voltage U_{V}, without the need for a high-voltage source.

The feedback loop via the switching device S₂ as well as the buffer capacitor C_{B} from the circuit 200 of FIG. 2A can also be eliminated, since the energy in the oscillation circuit is substantially retained except for the typical, in particular ohmic, losses, so that buffering is no longer necessary.

FIG. 13 illustrates a first exemplary embodiment 1300 of such a combined circuit for controlling an actuator, in particular a MEMS actuator, for driving an oscillating movement in a MEMS.

The circuit 1300 can be regarded as a further development or variant of the first circuit from FIG. 5, so that only the differences will be discussed below.

A key difference is that the circuit 1300 again contains a pausable oscillation circuit with the MEMS capacitor C_{M} as oscillation circuit capacitor and a oscillation circuit inductor L_{S} as well as a switching device S₇ for temporarily interrupting (pausing) the oscillation circuit.

To recharge the MEMS capacitor C_{M}, when it has reached its maximum voltage value within the current oscillation period, the oscillation circuit is interrupted (paused) by means of the switching device S₇ and, by closing at least one of the switching device S₂ and S₄, a current path is closed between the step-up converter circuit shown in the left part of FIG. 13 and the oscillation circuit, in particular the MEMS capacitor C_{M}. The step-up converter circuit is configured with respect to its switch positions (e.g.: S₁ and S₃ closed, S₂ and S₄ open or: S₁ and S₄ closed, S₂ and S₃ open) in such a way that it supplies a supply voltage to the oscillation circuit, or more precisely the MEMS capacitor C_{M}, which is copolar to the (positive) voltage U_{M} across the MEMS capacitor C_{M}.

On the other hand, to (additionally) recharge the MEMS capacitor C_{M} when it has reached its maximum voltage value within the current oscillation period, the oscillation circuit is once again interrupted (paused) by means of the switching device S₇ and, by closing the further switching devices S₃ and S₄, a current path is closed between the step-up converter circuit and the oscillation circuit, in particular the MEMS capacitor C_{M}. The step-up converter circuit is configured with respect to its switch positions (e.g.: S₁ and S₃ closed, S₂ and S₄ open; or: S₁ and S₄ closed, S₂ and S₃ open) in such a way that it supplies a supply voltage to the oscillation circuit, or more precisely the MEMS capacitor C_{M}, which is copolar to the (positive) voltage U_{M} across the MEMS capacitor C_{M}.

In the circuit 1300 as well, the oscillation circuit can therefore be supplied with energy solely by means of a low-voltage source to provide the supply voltage U_{V}, without the need for a high-voltage source. In addition, the buffer capacitor C_{B} from the circuit 500 of FIG. 5 can again be eliminated, since the energy in the oscillation circuit is essentially retained except for the typical, in particular ohmic, losses, so that buffering is no longer necessary.

FIG. 14 shows a third exemplary embodiment 1400 of a circuit in which the concepts of the first circuit and the second circuit are combined to form a circuit for bipolar and differential control of a MEMS actuator, in particular a microscanner.

The circuit 1400 comprises, in addition to an oscillation circuit 1425, which can be interrupted by means of a switching device 1405 and is thus pausable, two step-up converter circuits 1415 and 1420, which here each correspond, by way of example, to the concept of the circuit from FIG. 13 and which serve to provide two differently poled, boosted supply voltages +U_{V} and −U_{V}, respectively, for the pausable oscillation circuit 1425, one each at an associated feed point E₁ and E₂, respectively.

Recharging the MEMS capacitors C_{M1} and C_{M2} preferably takes place when they have reached their absolute maximum voltage value, which is the same pole as the assigned supply voltage, within the current oscillation period. The oscillation circuit is temporarily interrupted (paused) by means of a switching device 1415 with an associated control voltage source 1420. The first MEMS capacitor C_{M1} is thus charged in a first polarity (+) while at the same time the second MEMS capacitor C_{M2} is charged in a polarity opposite to the first polarity (−). Operation of the circuit is identical to that of FIG. 13 with respect to each of the polarities, wherein in this case a further index 1 or 2 is introduced in the reference numerals to distinguish the components of the two step-up converters 1415 and 1420, which can in particular be designed identically.

The control of the circuit 1400 is designed such that while the step-up converters 1415 and 1420 are operating, the switching device 1405 is open so that both step-up converters 1415 and 1420 can operate separately, each for themselves, to charge the MEMS capacitors C_{M1} and C_{M2} to mutually opposite voltage levels. If the oscillation circuit is subsequently activated, both step-up converters 1415 and 1420 are put into the “idle” state, so that they do not impair the function of the then oscillating oscillation circuit 1425.

FIG. 15 schematically shows a MEMS 1500 having a microscanner system with a microscanner 1501. The microscanner 1501 shows a support structure 1505 made of a semiconductor substrate in the form of a frame (chip frame) surrounding a deflection element (mirror) 1510 on all sides, the base of which is made of the same semiconductor substrate as the support structure 1505. The deflection element 1510 is suspended on the support structure 1505 by means of one or more spring elements, in this example these are the two spring elements 1515a and 1515b, which are placed on opposite sides of the deflection element 1510. This suspension is designed such that the 1055 deflection element can oscillate rotationally around at least one axis of vibration. This oscillation axis runs along the straight line (extending vertically in the image of FIG. 15) through the two starting points of the spring elements 1515a and 1515b at the deflection element 1510. With appropriate excitation, it is also possible to stimulate an oscillation around a second axis of vibration, orthogonal to the first, i.e., horizontal in the image of FIG. 15. In particular, for the promotion of such a two-dimensional oscillation, other shaped and arranged spring elements, in particular multiple spiral-shaped spring elements, may be provided instead of the suspension shown here with two opposite meandering spring elements.

On each of the spring elements 1515a and 1515b, there is a piezo element 1520 and 1525 respectively, although these piezo elements differ in terms of their piezo material and their tasks.

The first piezo element 1520 serves as a piezo-actuator for the oscillation movement of the deflection element 1510 and is therefore formed as a dielectric on the basis of a first piezo-material, such as PZT, which has a particularly strong piezoeffect. The electrodes of the piezo element 1520, which are separated from each other by the piezo material, also form the electrodes of its MEMS capacitor C_{M}. The first piezo element 1520 is therefore suitable, if the spring strengths of the spring elements 1515a and 1515b are suitably selected, to allow particularly large deflection and thus scanning angles of the microscanner 100, in particular up to +90° (optical scanning angle) or even more.

On the other hand, the second piezo element 1525 serves as a piezosensor for measuring and thus determining the time-dependent position, i.e., specifically the orientation or phase position of the oscillation, of the deflection element 1510.

FIG. 15 further shows the corresponding connection lines 1535a,b and 1545a,b respectively, as well as connection pads (bondpads) 1530a,b and 1540a,b respectively, connected thereto, for both piezo elements 1520 and 1525 to produce a respective electrical connection with an external drive or measuring electronics, for example, via wire bonds. It is also conceivable that other piezo elements in addition to the two pictured are provided as piezoreactors or piezosensors.

A SOI (Silicon-on-Insulator) substrate serves as the basis. On this substrate, a SiO₂ or other electrical passivation is produced, on which the piezoelectric layer stacks are applied. The piezoelectric strata stacks consist of a soil electrode, mostly metal, the piezoelectric material, and a top electrode, mostly metal. In addition, an additional electrical passivation is used between top and bottom electrodes to prevent electric short-circuiting.

To control the first piezo element 1520 (and optionally to process measurement signals of the second piezo element 1525), the MEMS 1500 additionally has a circuit 1550 according to any one of the aforementioned circuit-related aspects of the present solution, e.g., according to any one of FIG. 2A or 5 or 12 to 14. Depending on the circuit used, the piezo elements can be non-differential or differential.

### LIST OF REFERENCE NUMERALS

100 conventional regulated step-up converter circuit
200 first (unipolar) embodiment of a circuit according to the solution
205 comparison of circuits 100 and 200
300 plot against time of the current through the inductor L during the first circuit configuration
400 embodiment of a control device Ctrl
405 delay chain
405-x delay elements of the delay chain 405
410 multiplexers
415 RS flip-flop
500 second (bipolar) embodiment of a circuit according to the solution
600 plot against time of the configuration of the switching device of the circuit 500
700 conventional half-bridge circuit
705, 710 supply voltage sources
715, 725 switching devices
720, 730 control voltage sources
800 first exemplary embodiment of the second circuit
805 supply voltage source
815, 825 switching devices
820, 830 control voltage sources
900 current and voltage plots at the MEMS capacitor of circuit 800
1000 second exemplary embodiment of the second circuit
1005 supply voltage source
1015, 1025 switching devices
1020, 1030 control voltage sources
1035 additional switching device
1040 control voltage source for switching device 1035
1045 first mass
1050 second mass
1100 third exemplary embodiment of the second circuit
1105 supply voltage source
1115, 1125 switching devices
1120, 1130 control voltage sources
1200 first exemplary embodiment of a combined circuit
1300 second exemplary embodiment of a second circuit
1400 third exemplary embodiment of a second circuit
1405 switching device
1410 control voltage source for switching device 1405
1415 first step-up converter
1420 second step-up converter
1425 oscillation circuit
1500 MEMS
1501 microscanner
1505 support structure (chip frame)
1510 deflection element (mirror)
1515a first spring element
1515b second spring element
1520 first piezo element, piezoactuator
1525 second piezo element, piezosensor
15530a, b connection pads for the first piezo element
135a, b connection lines for the first piezo element
1540a, b connection pads for the second piezo element
1545a, b connection lines for the second piezo element
C buffer capacity in conventional circuit
C_{B} buffer capacitor for supply voltage source
C_{M} MEMS capacity
C_{M1}, C_{M}2 separate MEMS capacitors
Clk clock signal (Clock)
Ctrl controller or control device
D diode
E₁, E₂ feed points for electrical energy
I charging current
I₀ limit current
L inductor, in particular booster inductor
L_{S} oscillation circuit inductor, second coupling inductor
L_{V} first coupling inductor
OP operational amplifier
P period or period duration
P₁ first pole of the inductor L
P₂ second pole of the inductor L
Q output signal of Ctrl
R, S inputs of the RS flip-flop 415
Reg regulator
R₁, R₂ ohmic resistors that form voltage dividers
R_{L}, R_{L1}, R_{L2} ohmic resistance of the associated inductor L, L₁ or L₂
R_{S}, R_{V} ohmic resistances of the coupling inductors, in particular ohmic resistance in the oscillation circuit according to the equivalent circuit diagram
S₁-S₇ switching devices, in particular switching transistors
SEL selection signal
T transistor
t time variable
t₀, . . . , t₆ time intervals
U_{A} voltage across buffer capacitor C
U_{M} voltage across MEMS capacitor
U_{V} supply voltage or supply voltage source
V_{ref} reference voltage
+V, −V alternating voltage levels of U_{M}

What is claimed is:

1. A circuit for controlling an actuator for driving an oscillating movement of at least one movable component of a microelectromechanical system, MEMS, wherein:
the circuit comprises a step-up converter circuit with an inductor, an electrical MEMS capacitor, and a first switching device that can be controlled by a controller;
the MEMS capacitor is designed as a component of an actuator such that it forms a component of an electromechanical converter of the actuator, wherein the converter is configured to convert electrical energy stored in the MEMS capacitor into at least one mechanical variable for driving a movement of the actuator; and
the first switching device is adapted to assume a first circuit configuration and sequentially a second circuit configuration depending on the controller, wherein
in the first circuit configuration, a first current path through the inductor is continuously connected to cause an increasing current flow through the inductor fed by a supply voltage, and
in the second circuit configuration, a capacitor-unbuffered second current path is continuously connected between a first pole of the inductor and the MEMS capacitor in order to charge the MEMS capacitor to a first voltage by means of a current flow fed at least partially by the inductor, the amount of which is equal to or higher than the supply voltage.

2. The circuit of claim 1, wherein the controller is unregulated.

3. The circuit of claim 1, wherein the first switching device is further adapted to repeatedly temporarily switch a third current path continuously, such that the MEMS capacitor can be repeatedly, at least partially, discharged via this third current path in order to generate a supply voltage of the electromechanical converter at the MEMS capacitor, which supply voltage is variable in magnitude over time.

4. The circuit of claim 3, wherein the third current path is led to a buffer capacitor for buffering the supply voltage in order to transfer charge from the MEMS capacitor to the buffer capacitor when the former is discharged.

5. The circuit of claim 1, wherein the first switching device is further adapted to repeatedly and temporarily establish a fourth current path between the MEMS capacitor and a second pole of the inductor that is electrically opposite to the first pole, in a period in which the second current path is not continuously connected, such that the MEMS capacitor is charged to a second voltage with a polarity opposite to the polarity of the first voltage.

6. The circuit of claim 5, wherein the switching device comprises:
a first switch, S₁, for switching an electrical connection between the supply voltage and the second pole of the inductor;
a second switch, S₂, electrically connected to the first pole of the inductor for switching the first current path to allow passage or interrupting it;
a third switch, S₃, electrically connected to the first pole of the inductor for switching the second current path to allow passage or interrupting it; and
a fourth switch, S₄, electrically connected to the second pole of the inductor and the MEMS capacitor for switching the fourth current path to allow passage or interrupting it.

7. The circuit of claim 6, further comprising a fifth switch, S₅, for switching a current path between the second pole of the inductor and ground to allow passage or interrupting it.

8. The circuit of claim 6 or 7, wherein the controller is configured to set the switching device step by step into different switching states according to the following sequence, wherein the sequence is run through at least once:
(a) S₁ and S₂ closed, S₃ and S₄ open;
(b) S₁ and S₃ closed, S₂ and S₄ open;
(c) S₂ and S₃ closed, S₁ and S₄ open;
(d) S₁ and S₂ closed, S₃ and S₄ open;
(e) S₂ and S₄ closed, S₁ and S₃ open; and
(f) S₂ and S₃ closed, S₁ and S₄ open.

9. The circuit of claim 8, wherein the circuit has a buffer capacitor, in particular a capacitor, for capacitive buffering of the supply voltage and the sequence additionally has a further switching state (b1) which lies between the switching states (b) and (c) and is characterized in that in this state S₁ and S₄ are closed and S₂ and S₃ are open.

10. The circuit of claim 8, wherein the sequence additionally comprises a further switching state (b2) which lies between the switching states (b) and (c), and is characterized in that in this state S₂ and S₄ are closed and S₁ and S₃ are open.

11. The circuit of claim 7, wherein the sequence additionally comprises a further switching state (e1) which follows the switching state (e) and precedes the switching state (f) and which is characterized in that in this state S₄ and S₅ are closed and S₁, S₂, and S₃ are open.

12. The circuit of claim 1, wherein the controller comprises a multi-stage delay chain and a multiplexer for tapping the respective output signals of the stages of the delay chain in a time-staggered manner in order to generate a time-variable control signal for driving the first switching device.

13. The circuit of claim 12, wherein the first switching device can be controlled by means of the control signal such that switching between the first switching configuration and the second switching configuration, or vice versa, can be effected by means of the control signal.

14. The circuit of claim 1, further comprising an oscillation circuit having a capacitor which is at least partially defined by the MEMS capacitor, having an oscillation circuit inductor, and having a controllable second switching device for selectively interrupting or closing the oscillation circuit depending on a control of the second switching device;
wherein the oscillation circuit comprises a resonance frequency related to a permanently closed state of the oscillation circuit; and
wherein the controller is further configured to control the second switching device such that it temporarily opens the second switching device for a specific portion of the oscillation period during a respective oscillation period of the oscillation circuit to thereby cause an interruption of the oscillation circuit and thus an actual oscillation frequency of the oscillation circuit which is lower than the resonance frequency.

15. A MEMS, comprising:
a mass element configured to oscillate;
an actuator for driving an oscillating movement of the mass element; and
a circuit of claim 1 for controlling the actuator such that the actuator is caused to move the oscillatory mass element in an oscillating movement;
wherein the MEMS capacitor is designed as a component of the actuator such that it itself forms a component of an electromechanical converter of the actuator, and the converter is configured to convert electrical energy stored in the MEMS capacitor into at least one mechanical variable for driving a movement of the actuator to thereby drive the oscillating movement of the mass element.

16. The MEMS of claim 15, wherein the MEMS comprises a microscanner system; and the mass element is designed as an oscillatory deflection element of the microscanner system for deflecting electromagnetic radiation.

17. The circuit of claim 2, wherein the first switching device is further adapted to repeatedly temporarily switch a third current path continuously, such that the MEMS capacitor can be repeatedly, at least partially, discharged via this third current path in order to generate a supply voltage of the electromechanical converter at the MEMS capacitor, which supply voltage is variable in magnitude over time.

18. The circuit of claim 2, wherein the first switching device is further adapted to repeatedly and temporarily establish a fourth current path between the MEMS capacitor and a second pole of the inductor that is electrically opposite to the first pole, in a period in which the second current path is not continuously connected, such that the MEMS capacitor is charged to a second voltage with a polarity opposite to the polarity of the first voltage.

19. The circuit of claim 7, wherein the controller is configured to set the switching device step by step into different switching states according to the following sequence, wherein the sequence is run through at least once:
(a) S₁ and S₂ closed, S₃ and S₄ open;
(b) S₁ and S₃ closed, S₂ and S₄ open;
(c) S₂ and S₃ closed, S₁ and S₄ open;
(d) S₁ and S₂ closed, S₃ and S₄ open;
(e) S₂ and S₄ closed, S₁ and S₃ open; and
(f) S₂ and S₃ closed, S₁ and S₄ open.

20. The circuit of claim 9, wherein the sequence additionally comprises a further switching state (b2) which lies between the switching states (b) and (c), and is characterized in that in this state S₂ and S₄ are closed and S₁ and S₃ are open.
